(19) United States
(12) Patent Application Publication
(10) Pub. No.: US 2026/0040695 A1
(43) Pub. Date: Feb. 5, 2026

(54) A METHOD TO GENERATE CONDUCTIVE POLYMER

(71) Applicant: NEWSOUTH INNOVATIONS PTY LIMITED, Sydney, New South Wales (AU)

(72) Inventors: Xiaojing HAO, Sydney, New South Wales (AU); Martin Andrew GREEN, Sydney, New South Wales (AU); Ziheng LIU, Sydney, New South Wales (AU); Caixia LI, Sydney, New South Wales (AU); Pengfei ZHANG, Sydney, New South Wales (AU)

(21) Appl. No.: 19/099,438

(22) PCT Filed: Jul. 28, 2023
(86) PCT No.: PCT/AU2023/050702

§ 371 Date: Jan. 28, 2025

(30) Foreign Application Priority Data
Jul. 29, 2022 (AU) 2022902141

(51) Int. Cl. H10F 19/90; C08J 3/28; C08J 5/12; C09J 9/02; H01B 1/12; H10F 19/40; H10F 77/00

(52) U.S. Cl. CPC H10F 19/906; C08J 3/28; C08J 5/121; C09J 9/02; H01B 1/124; H10F 19/40; H10F 77/939; C08J 2300/12; C09J 2203/326; C09J 2301/314

(57) ABSTRACT

Polymer materials, in particular materials including one or more polymers where the degree of electrical conductivity may be controlled. Materials, for example one or more polymers (or monomers and/or oligomers), optionally one or more easily-processable, thermo-transformable polymers, including one or more electron rich domains, which can be exposed to at least one of: sufficient temperature (for example for temperature-dependent processing), a mechanical force/pressure, magnetic field and/or an electric field, and consequently increase the conductivity of the materials. Methods of forming the materials and applications and uses thereof.

### CROSS-REFERENCE TO RELATED APPLICATIONS

The present application claims priority from Australian Provisional Patent Application No 2022902141 filed on 29 Jul. 2022, the contents of which are incorporated herein by reference in their entirety.

### TECHNICAL FIELD

The present disclosure relates to polymer materials, in particular materials comprising one or more polymers (or optionally monomers and/or oligomers) where the degree of electrical conductivity may be controlled before, during or after polymerisation. Disclosed herein are materials, for example one or more polymers, optionally one or more easily-processable, thermo-transformable polymers, comprising one or more electron rich domains, which can be exposed to at least one of: sufficient temperature (for example for temperature-dependent processing), a mechanical force/pressure, magnetic field and/or an electric field, and consequently increase the conductivity of the materials. The materials may be used as conductive adhesives, memory storage or conductive layers in electronic devices, for example transparent conductive adhesives. The increase in conductivity may be reversible, or partially reversible.

### BACKGROUND

Conductive materials can be applied in different circumstances for a variety of different applications. However the production of such materials can be high-cost, laborious and time consuming. In addition, the materials may only provide a limited number of required physical characteristics.

There is a need to provide methods for the production of conductive materials possessing a raft of physical, chemical and electronic characteristics. The ability to enhance a materials' electronic conductivity or convert materials with poor or minimal electronic conductivities into electronically conductive materials would increase the choices available when selecting (and tailoring), materials, optionally plate materials, for one or more particular applications.

There are two broad classes of conductive polymers. In some circumstances extrinsic conductive polymers may be used. However, these types of materials generally require the introduction of further substances; for example: conductive particles (including metallic spheres, such as indium tin oxide), silver nanowires, graphene sheets, in order to obtain a conductive material. In applications that require the transmittance of light, the inclusion of these type of substances can potentially block light and lead to optical loss. In other circumstances, intrinsic conductive polymers, such as poly(3,4-ethylenedioxythiophene)polystyrene sulfonate (PEDOT:PSS), which allow the electrical transport without the mixture of conductive materials, could be used. However, the relatively high cost, weak mechanical intensity, and parasitic absorption loss limit (the latter being a potential issue in applications encompassing solar cells), can raise a series of issues.

Any discussion of documents, acts, materials, devices, articles or the like which has been included in the present specification is not to be taken as an admission that any or all of these matters form part of the prior art base or were common general knowledge in the field relevant to the present disclosure as it existed before the priority date of each claim of this application.

### SUMMARY

Herein, a technique has been developed to control the electrical conductivity of materials, such as polymers. After an appropriate treatment the electrical conductivity of one or more polymers may be increased. After some other treatment, the increase in electrical conductivity may be reversible, or partially reversible whilst, ideally, maintaining all, or substantially all, other mechanical and/or optical properties.

The developed technique may be used with one or more polymers comprising particular groups and/or substituents, for example electron rich domains. In an advantageous embodiment, a simple process is used to control the electrical conductivity of one or more low-cost materials. In one embodiment the electronic conductivity of a conducting polymer may be improved. In one embodiment, insulating materials may be adapted so that they are able to conduct an electric charge. For applications such as the formation of the transparent conductive adhesive, the methods disclosed herein may be used to produce materials with appropriate and/or improved electrical, physical/mechanical, and/or chemical properties.

In a first aspect, disclosed herein is a polymer material comprising one or more polymers (or optionally monomers, oligomers), optionally one or more insulating polymers or one or more conductive polymers, comprising one or more electron rich domains, wherein when:
a sufficiently strong electric field is applied across the one or more polymers and/or
a sufficiently strong magnetic field is applied across the one or more polymers; and/or
a sufficiently high temperature is applied across the one or more polymers; and/or
a sufficiently strong pressure is applied across the one or more polymers,
   the electrical conductivity of the polymer material (or optionally monomers, oligomers) is increased.

In one embodiment of the first aspect, a sufficiently strong electric field is applied across the one or more polymers. In one embodiment of the first aspect a sufficiently strong magnetic field is applied across the one or more polymers. In one embodiment of the second aspect a sufficiently strong magnetic field is applied across the one or more polymers. In one embodiment of the second aspect a sufficiently high temperature is applied across the one or more polymers.

In another embodiment of the first aspect, disclosed herein is a polymer material comprising one or more polymers (or optionally monomers and/or oligomers), optionally one or more insulating polymers or one or more conductive polymers, comprising one or more electron rich domains, wherein when two or more of:
a sufficiently strong electric field is applied across the one or more polymers and/or
a sufficiently strong magnetic field is applied across the one or more polymers; and/or
a sufficiently high temperature is applied across the one or more polymers; and/or
a sufficiently strong pressure is applied across the one or more polymers,
   the electrical conductivity of the polymer material (or optionally monomers, oligomers) is increased. Where a plurality of conditions/stimuli are used, there may be an order/sequence. For example, altering the temperature is optionally first, wherein the purpose may be to make the polymer material (or optionally monomers and/or oligomers), processable. In cases where the polymer (or optionally monomers and/or oligomers) are already in a processable (for example, gel, melted or liquid) state, they could can be made in to a film directly without extra high temperature. In some embodiments, for example with long-chain polymers, specific temperatures and/or ranges may be needed. Following the adjustment of temperature, second may be a change of pressure. The application of a specific pressure and/or range for pressures may be used to reduce the thickness of a polymer along at least one dimension, and/or to introduce certain microstructures. Following the changes in temperature and/or pressure, an electric and/or magnetic field can be applied at last for the final conductivity.

In some embodiments, potential advantages of the disclosure herein, may include, but are not limited to one or more of:
the transformation of insulating material to conductive material without the need for doping the polymer with localised charge carriers
improving the electrical conductivity of a conducing material (for example one or more intrinsically and/or extrinsically conducting polymer)
a reversible increase in electrical conductivity of the polymer
translatability across a broad class of polymer classes and/or
a tailorable resistance based on selection of the film thickness, the strength of the electric field used, and polymer used.

It will be appreciated that the embodiments of each aspect of the present disclosure may equally be applied to each other aspect, mutatis mutandis.

### BRIEF DESCRIPTION OF DRAWINGS

Whilst it will be appreciated that a variety of embodiments disclosed herein may be utilised, described herein are a number of examples with reference to the following drawings:

FIG. 1. Schematic of the setup for electrical treatment and electrical characterisation of Si/polymer/Si sample.

FIG. 2. Schematic of the bonded III-V cells on (a) Si wafer, (b) indium tin oxide (ITO) glass, (c) Si cell by polymer layer, and (d) schematic of top cell bonded on bottom cell by polymer layer.

FIG. 3. Dependence of epoxy thickness on the spin speed. The error bars indicate standard deviations.

FIG. 4. (a) IV sweep curves of Si wafers bonded by epoxy layers with different thicknesses. (b) Dependence of voltage V on the thickness of the polymer layer d.

FIG. 5. (a) The IV curve of polymer-bonded Si wafers after cyclic electrical treatment. (b) Resistance of EVA-bonded Si wafers after electrical treatment with different electrical field strength.

FIG. 6. AFM height (a-c) and phase (d-f) mapping images (1 μm scan) of EVA (an example polymer) films of 5 μm thickness. Untreated EVA films demonstrate randomly arranged polymer chains, while the polymer chains start to aggregate after 1V/μm electric field treatment and form partially ordered arrays after 2V/μm treatment.

FIG. 7. (a) Schematic of the bonded ITO glasses by polymer layer. (b) Measured transmission of bonded ITO glasses by polymer layer before and after the standard cyclic electrical treatment.

FIG. 8. (a) Equivalent circuit diagram of the III-V cell bonded on Si wafer by polymer layer. (b) Measured IV curves between T2 and T3 before and after the electrical treatment.

FIG. 9. JV curves of the III-V solar cell bonded on Si wafer via polymer layer which measured through different terminals before and after the standard cyclic electrical treatment.

FIG. 10. fill factor (FF) and open circuit voltage (V_{OC}) of the bonded III-V cell on Si wafer by polymer layer over 120 days.

FIG. 11. (a) The equivalent circuit diagram of bonded III-V cell on ITO glass by polymer layer. (b) Measured IV curves between T2 and T3 before and after the standard cyclic electrical treatment. (c) JV curves of the III-V cell bonded on ITO glass by polymer layer which is measured through different terminals before and after the electrical treatment.

FIG. 12. Measured transmission of bonded III-V cell on ITO glass by polymer layer before and after the cyclic electrical treatment.

FIG. 13. (a) Schematic of GaInP/GaAs//Si tandem solar cells bonded by polymer layer. The multiple optical enhancement layers (MOELs) include TiO₂ layers at the front and back side of the III-V cell, and a textured PDMS film on the front side of tandem cell after TiO₂. (b) SEM image of the cross-section of the bonding interface. (c) Measured IV curves between T2 and T3 before and after the standard cyclic electrical treatment.

FIG. 14. The JV curves of GaInP/GaAs//Si tandem solar cells, III-V top cell, and Si bottom cell after the electrical treatment of polymer layer.

FIG. 15. Diagram outlining an exemplified process for applying heat and/or pressure to a polymer-based sample.

### DETAILED DESCRIPTION

### General Definitions and Terms

With regards to the definitions provided herein, unless stated otherwise, or implicit from context, the defined terms and phrases include the provided meanings. In addition, unless explicitly stated otherwise, or apparent from context, the terms and phrases below do not exclude the meaning that the term or phrase has acquired by a person skilled in the relevant art. The definitions are provided to aid in describing particular embodiments, and are not intended to limit the claimed invention, because the scope of the invention is limited only by the claims.

All publications discussed and/or referenced herein are incorporated herein in their entirety, unless described otherwise.

Unless otherwise required by context, singular terms shall include pluralities and plural terms shall include the singular. Throughout this disclosure, unless specifically stated otherwise or the context requires otherwise, reference to a single step, composition of matter, group of steps or group of compositions of matter shall be taken to encompass one and a plurality (i.e. one or more) of those steps, compositions of matter, groups of steps or groups of compositions of matter. Thus, as used herein, the singular forms “a”, “an” and “the” include plural aspects unless the context clearly dictates otherwise. For example, reference to “a” includes a single as well as two or more; reference to “an” includes a single as well as two or more; reference to “the” includes a single as well as two or more and so forth.

Those skilled in the art will appreciate that the disclosure herein is susceptible to variations and modifications other than those specifically described. It is to be understood that the disclosure includes all such variations and modifications. The disclosure also includes all of the examples, steps, features, methods, compositions, formulations, and processes, referred to or indicated in this specification, individually or collectively, and any and all combinations or any two or more of said steps or features.

The term “and/or”, e.g. “X and/or Y” shall be understood to mean either “X and Y” or “X or Y” and shall be taken to provide explicit support for both meanings or for either meaning.

Unless otherwise indicated, the terms “first,” “second,” etc. are used herein merely as labels, and are not intended to impose ordinal, positional, or hierarchical requirements on the items to which these terms refer. Moreover, reference to a “second” item does not require or preclude the existence of lower-numbered item (e.g. a “first” item) and/or a higher-numbered item (e.g. a “third” item).

As used herein, the phrase “at least one”, “one or more”, when used with a list of items, means different combinations of one or more of the listed items may be used and only one of the items in the list may be needed. The item may be a particular object, thing, or category. In other words, “at least one” or “one or more” means any combination of items or number of items may be used from the list, but not all of the items in the list may be required. For example, “at least one of item A, item B, and item C” may mean item A; item A and item B; item B; item A, item B, and item C; or item B and item C. In some cases, “at least one of item A, item B, and item C” may mean, for example and without limitation, two of item A, one of item B, and ten of item C; four of item B and seven of item C; or some other suitable combination.

It is to be appreciated that certain features that are, for clarity, described herein in the context of separate embodiments, may also be provided in combination in a single embodiment. Conversely, various features that are, for brevity, described in the context of a single embodiment, may also be provided separately or in any sub-combination.

Throughout the present specification, various aspects and components of the disclosure can be presented in a range format. The range format is included for convenience and should not be interpreted as an inflexible limitation on the scope of the present disclosure. Accordingly, the description of a range should be considered to have specifically disclosed all the possible sub-ranges as well as individual numerical values within that range, unless specifically indicated. For example, description of a range such as from 1 to 5 should be considered to have specifically disclosed sub-ranges such as from 1 to 3, from 1 to 4, from 1 to 5, from 2 to 4, from 2 to 5, from 3 to 5 etc., as well as individual and partial numbers within the recited range, for example, 1, 2, 3, 4, 4.5 and 5, unless where integers are required or implicit from context. This applies regardless of the breadth of the disclosed range. Where specific values are required, these will be indicated in the specification.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

Throughout this specification, the term “consisting essentially of” is intended to exclude elements which would materially affect the properties of the claimed composition, method or process.

The terms “comprising”, “comprise” and “comprises” herein are intended to be optionally substitutable with the terms “consisting essentially of”, “consist essentially of”, “consists essentially of”, “consisting of”, “consist of” and “consists of”, respectively, in every instance.

Herein the term “about” encompasses a 10% tolerance in any value or values connected to the term.

Herein “weight %” may be abbreviated to as “wt %” or “wt. %”. The weight % may be w/w or w/v, unless specifically indicated or clear from context.

The terms “optionally substituted”, “comprises one or more substituents” or “substituted” means that a corresponding radical, atom, group or moiety on a compound may have one or more substituents present. Where a plurality of substituents, or a selection of various substituents is specified, the substituents are selected independently of one another and do not need to be identical. In some cases, at least one hydrogen atom on the radical, group or moiety is replaced with a substituent. In the case of an oxo substituent (═O) two hydrogen atoms may be replaced. In this regard, substituents may include one or more: alkyl, alkenyl, alkynyl, carbocyclyl, halogen, nitro, cyano, hydroxy, sulfonic, thiol, ether, amino, alkylamino, dialkylamino, haloalkyl, hydroxyalkyl, alkoxy, haloalkoxy, aryloxy, heteroaryloxy, aralkyloxy, alkylthio, carboxamido, sulfonamido, alkylcarbonyl, arylcarbonyl, alkylsulfonyl, arylsulfonyl, carboxy, carboxyalkyl, alkyl, cycloalkyl, alkenyl, alkynyl, aryl, heteroaryl, heterocyclo, alkoxyalkyl, (amino)alkyl, hydroxyalkylamino, (alkylamino)alkyl, (dialkylamino)alkyl, (cyano)alkyl, (carboxamido)alkyl, mercaptoalkyl, (heterocyclo)alkyl, (cycloalkylamino)alkyl, (C₁-C₄ haloalkoxy)alkyl, (heteroaryl)alkyl, or perylene, oxo, heterocycle, —OR^{x}, —NR^{x}R^{Y}, —NR^{x}C(═O)R^{y}—NR^{x}SO₂R^{y}, —C(═O)R^{x}, —C(═O)OR^{x}, —C(═O)NR^{x}R^{y}, —SO_{q}R^{x}, —SO_{q}NR^{x}R^{y}, and mixtures thereof, wherein q is 0, 1 or 2, Rx and Ry are the same or different and independently selected from hydrogen, alkyl or heterocycle, and each of said alkyl and heterocycle substituents may be further substituted with one or more of oxo, halogen, —OH, —CN, alkyl, —OR^{x}, heterocycle, —NR^{x}R^{y}, —NR^{x}C(═O)R^{y}—NR^{x}SO₂R^{y}, —C(═O)R^{x}, —C(═O)OR^{x}, —C(═O)NR^{x}R^{y}, —SOR^{x} and —SONR^{x}R^{y}.

Herein a material, for example one or more polymers may be regarded as, be utilised as part of an adhesive. The material may show enhanced adhesivity or tack, such that the material enhances aggregation of articles, or parts thereof, for example acting as an adhesive for a plurality of other materials.

Herein “insulating” or “insulator”, for example “insulating polymer”, refer to a material and a property of a material, respectively, which have high values of electrical resistivity. The electrical resistivity of insulators may be in the range of 10⁸ Ωm or more.

Herein “electron rich domain” may refer to any functional group/groups consist of free electron pair, or inorganic atoms with flexible electrons, such as Li, Cu, Fe, Si, S, O, F, Br, and mixtures thereof. To be more specific, the “electron rich domain” can be defined as any chemical part containing electron dipoles with dipole moment larger than 0.

Herein “conductive adhesive” refers to a material capable of adhering for a period of time to at least one surface, or a portion thereof of an article. In one embodiment the “conductive adhesive” is capable of joining at least a portion of two or more articles, and provides both a physical connection and electrical connection. In some embodiments, the “conductive adhesive”, may be a “transparent conductive adhesive”.

Herein a “transparent conductive adhesive” refers to a material capable of adhering for a period of time to at least one surface, or a portion thereof of an article. In one embodiment the “transparent conductive adhesive” is capable of joining at least a portion of two or more articles, and provides both a physical connection and electrical connection. Herein the transparent conductive adhesive allows for the passage of light/electromagnetic radiation, for example infra-red, ultra violet and/or visible light. In one embodiment, the transparency is measured according to the percentage difference in optical transmission before and after a film layer is applied to ITO glass. In one embodiment, the percentage difference in optical transmission of light in the wavelengths in the range of between about 300 nm to about 1300 nm to ITO glass before and after a film layer is applied is less than about 5%, for example less than about: 5%, 4.5%, 4% 3.5% or 3%.

Disclosed herein is a polymer material comprising one or more polymers (or optionally monomers and/or oligomers), optionally one or more insulating polymers or one or more conductive polymers, comprising one or more electron rich domains, wherein when at least one of:
a sufficiently strong electric field is applied across the one or more polymers and/or
a sufficiently strong magnetic field is applied across the one or more polymers; and/or
a sufficiently high temperature is applied across the one or more polymers; and/or
a sufficiently strong pressure is applied across the one or more polymers,
   the electrical conductivity of the polymer material is increased.

Also disclosed herein is a polymer material comprising one or more polymers (or optionally monomers and/or oligomers), optionally one or more insulating polymers or one or more conductive polymers, comprising one or more electron rich domains, wherein when:
the polymer material is disposed between a plurality of layers, each layer independently selected from: one or more metals, one or more semiconductors, one or more materials capable conducting a charge, and mixtures thereof; and
at least one of:
   a sufficiently strong electric field is applied across the one or more polymers; and/or
   a sufficiently strong magnetic field is applied across the one or more polymers; and/or
   a sufficiently high temperature is applied across the one or more polymers; and/or
   a sufficiently strong pressure is applied across the one or more polymers,
      the electrical conductivity of the polymer material is increased.

Herein, the electrical conductivity of the polymer material may be increased as a result of at least one, two, three or four of: a sufficiently strong electric field is applied across the one or more polymers; and/or a sufficiently strong magnetic field is applied across the one or more polymers; and/or a sufficiently high temperature is applied across the one or more polymers; and/or a sufficiently strong pressure is applied across the one or more polymers.

Also disclosed herein is an electrically conductive polymer material formed from a polymer material as described herein, wherein the one or more polymers, optionally one or more insulating polymers, are exposed to the sufficiently strong electric field. Also disclosed herein is an electrically conductive polymer material formed from a polymer material as described herein, wherein the one or more polymers, optionally one or more insulating polymers, are exposed to the sufficiently strong magnetic field. Also disclosed herein is an electrically conductive polymer material formed from a polymer material as described herein, wherein the one or more polymers, optionally one or more insulating polymers, are exposed to the sufficiently high temperature. Also disclosed herein is an electrically conductive polymer material formed from a polymer material as described herein, wherein the one or more polymers, optionally one or more insulating polymers, are exposed to the sufficiently high pressure.

In one embodiment the electrically conductive polymer material is a conductive adhesive. In another embodiment, the electrically conductive polymer material is a transparent conductive polymer, such as a transparent conductive adhesive.

Also disclosed herein is a method of producing an electrically conductive polymer material, the method comprising applying at least one of:
a sufficiently strong electric field; and/or
a sufficiently strong magnetic field; and/or
a sufficiently high temperature; and/or
a sufficiently strong pressure,
   across one or more polymers (optionally one or more insulating polymers), comprising one or more electron rich domains, wherein the electrical conductivity of the one or more polymers (optionally one or more insulating polymers) is increased is increased.

Also disclosed herein is a method of improving the electrical conductivity of a polymer material comprising one or more polymers (or optionally monomers and/or oligomers), the method comprising applying at least one of:
a sufficiently strong electric field; and/or
a sufficiently strong magnetic field; and/or
a sufficiently high temperature; and/or
a sufficiently strong pressure,
   across the one or more polymers comprising one or more electron rich domains, wherein the electrical conductivity of the conductive polymer material is increased.

Also disclosed herein is a method of producing an electrically conductive polymer material, the method comprising:
disposing one or more polymers (optionally one or more insulating polymers), comprising one or more electron rich domains between a plurality of layers, each layer independently selected from: one or more metals, one or more semiconductors, one or more materials capable conducting a charge, and mixtures thereof; and
applying at least one of:
   a sufficiently high electric field; and/or
   a sufficiently high magnetic field; and/or
   a sufficiently high temperature; and/or
   a sufficiently strong pressure,
      across the one or more polymers, wherein the electrical conductivity of the one or more polymers (or optionally monomers, oligomers) is increased.

Also disclosed herein is the use of one or more polymers (optionally one or more insulating polymers), comprising one or more electron rich domains in a polymer material, to produce an electrically conductive polymer, wherein when at least one of:
a sufficiently strong electric field; and/or
a sufficiently strong magnetic field; and/or
a sufficiently high temperature; and/or
a sufficiently strong pressure,
   is applied across the one or more polymers, the electrical conductivity of the polymer material is increased.

Also disclosed herein is the use of one or more polymers (or optionally monomers, oligomers), optionally one or more insulating polymers, for physically and electronically connecting a plurality of layers, each layer independently selected from: one or more metals, one or more semiconductors, one or more materials capable conducting a charge, and mixtures thereof, wherein when:
the one or more polymers, are disposed between the plurality of layers and
at least one of:
   a sufficiently strong electric field; and/or
   a sufficiently strong magnetic field; and/or
   a sufficiently high temperature; and/or
   a sufficiently strong pressure,
is applied across the one or more polymers,
   the electrical conductivity of the one or more polymers (or optionally monomers, oligomers), is increased.

Also disclosed herein is an electrically conductive polymer material obtained from a method as described herein.

Also disclosed herein is a device comprising an electrically conductive polymer material as described herein.

### Conductive Materials

The present disclosure is directed to polymer materials, electrically conductive polymer materials, methods of formation, uses, and applications thereof.

In one embodiment the electrically conductive polymer material is a conducting adhesive. In another embodiment, the electrically conductive polymer material is a transparent conducting adhesive.

Herein, in one or more embodiments, the “polymer” or “one or more polymers” may be replaced, at least in part or fully with precursors and/or building blocks used in the formation of said polymer or one or more polymers, for example by one or more monomers and/or oligomers. These monomers and/or oligomers may be commercial monomers or oligomers. The electrical conductivity of the polymer, or one or more monomers and/or oligomer may be altered prior to, during and/or after a polymerisation process. For example at least one of at least one of: a sufficiently strong electric field; and/or a sufficiently strong magnetic field; and/or a sufficiently high temperature; and/or a sufficiently strong pressure, may be applied to at least one of the polymer, monomer and/or oligomer.

In one embodiment, an electric field is applied to one or more polymers, for example one or more insulating polymers. In another embodiment, an electric field is applied to one or more electrically conductive polymers. The electric field may have a strength of at least 5 V/m. Herein the electric field may be produced by introducing a potential difference across one axis of the one or more polymers. When one or more polymers are exposed to an electric field, the resulting electrical conductivity may be a result of a number of factors including, but not limited to, one or more of: the type of polymer or polymers, one or more dimensions of the polymer (for example the thickness, and/or the size of the electric field or a potential applied across and axis or plane of one or more polymers. The strength of the required electric field is dependent on, amongst other properties, the composition of the one or more polymers and the thickness of the one or more polymers film.

In one embodiment, a voltage in a range of about 0.05 V to about 100 V may be applied across the one or more polymers. In one embodiment a voltage of about, or at least about: 0.05 V, 0.1 V, 0.5V, 1 V, 2 V, 5 V, 10 V, 20 V, 50 V, or 100 V, may be applied.

Herein, the one or more polymers may be exposed to a single electric field, or a plurality of electric fields. Where a plurality of electric fields are used, the strength of each of said electric fields may be the same or different from a preceding or following electric field.

In one embodiment, a magnetic field is applied to one or more polymers, for example one or more insulating polymers. In another embodiment, a magnetic field is applied to one or more electrically conductive polymers. The magnetic field may have a strength of at least 2 T. Herein the magnetic field may be produced by a process known in the art, including, but not limited to magnets and/or Hall-effect generator across at least one axis of the one or more polymers. When one or more polymers are exposed to an appropriate magnetic field, the resulting electrical conductivity may be a result of a number of factors including, but not limited to, one or more of: the type of polymer or polymers, one or more dimensions of the polymer (for example the thickness, and/or the size of the magnetic field across and axis or plane of one or more polymers. The strength of the required magnetic field is dependent on, amongst other properties, the composition of the one or more polymers and the thickness of the one or more polymers film.

Herein, the one or more polymers may be exposed to a single magnetic field, or a plurality of magnetic fields. Where a plurality of magnetic fields are used, the strength of each of said magnetic fields may be the same or different from a preceding or following magnetic field.

In one embodiment, pressure is applied to one or more polymers, for example one or more insulating polymers. In another embodiment, pressure is applied to one or more electrically conductive polymers. The pressure may be at least 20 Pa (N/m²). Herein the pressure may be produced by any method known in the art, for example a weight applied evenly, the use of clips, the use of a laminator and/or an apparatus that can produce pressure. When one or more polymers are exposed to at least one appropriate pressure, the resulting electrical conductivity may be a result of a number of factors including, but not limited to, one or more of: the type of polymer or polymers, one or more dimensions of the polymer (for example the thickness, and/or the magnitude of the pressure being applied to one or more polymers. The pressure required is dependent on, amongst other properties, the composition of the one or more polymers and the thickness of the one or more polymers film.

Herein, the one or more polymers may be exposed to a single pressure, or a plurality of pressures. Where a plurality of pressures are used, the magnitude of said pressures may be the same or different from a preceding or following pressure.

In one embodiment, a specific temperature or range of temperatures is or are applied to one or more polymers, for example one or more insulating polymers. The temperature may relate to a glass transition temperature of one or more polymers that are used. In another embodiment, a specific temperature or range of temperatures is or are is applied to one or more electrically conductive polymers. The temperature may be as low as room temperature (for example about 20, 21, 22, 23, 24 or 25° C.), or even lower, for example a temperature above the glass transition temperature of used polymers. The temperature may be about, at least about, or less than about: 20° C., 30° C., 40° C., 50° C., 60° C., 70° C., 80° C., 90° C., 100° C., 110° C., 120° C., 130° C., 140° C., 150° C., 160° C., 170° C., 180° C., 190° C., or 200° C. Herein the appropriate temperature may be produced by any method known in the art, for example using a hotplate. When one or more polymers are exposed to at least one appropriate temperature, the resulting electrical conductivity may be a result of a number of factors including, but not limited to, one or more of: the type of polymer or polymers, one or more dimensions of the polymer (for example the thickness, and/or the specific temperatures or range of temperatures being applied to one or more polymers. The pressure required is dependent on, amongst other properties, the composition of the one or more polymers and the thickness of the one or more polymers film.

Herein, the one or more polymers may be exposed to a single temperature, or a plurality of temperatures. Where a plurality of temperatures are used, the magnitude of said temperatures may be the same or different from a preceding or following temperature.

Herein the polymer, monomer and/or oligomer may be exposed to at least one of: a sufficiently strong electric field is applied across the one or more polymers; and/or a sufficiently strong magnetic field is applied across the one or more polymers; and/or a sufficiently high temperature is applied across the one or more polymers; and/or a sufficiently strong pressure is applied across the one or more polymers, for a sufficient amount of time, dependent on the action and/or polymer (or monomers and/or oligomers), and may be on the scale of minutes or seconds.

Herein the increase in electrical conductivity may be measured by any appropriate method known in the art. As known in the art, conductivity (σ) is reciprocal of resistivity (ρ), i.e. σ=1/ρ. The resistivity can be calculated by using the equation ρ=RA/L, wherein R is the resistance of a specimen, A is the cross-sectional area A, and L is the length/thickness. L could be measured by a process known in the art, for example using cross-section microscopy images (e.g. scanning electron microscopy) and/or a profilometer. The resistance R can be measured by I-V testing. In one embodiment a four-point probe resistance measurement could be used as a method for measuring electrical resistance, and quantify said resistance. For example: U. Heitmann et al., Electrical and optical analysis of a spray coated transparent conductive adhesive for two-terminal silicon based tandem solar cells [C], AIP Conference Proceedings, AIP Publishing, 2019, 2147(1); and/or M. Taklo et al., Anisotropic Conductive Adhesive for Wafer-to-Wafer Bonding, Proceedings of 7^{th} International Conference and Exhibition on Device Packaging, 2011.

In one embodiment the increase in conductivity (in unit of S/m) may be by at least, or about: 1, 1.00E+01, 1.00E+02, 1.00E+03, 1.00E+04, 1.00E+05, 1.00E+06, 1.00E+07, 1.00E+08, 1.00E+09, 1.00E+10, 1.00E+11, 1.00E+12, 1.00E+13, 1.00E+14, 1.00E+15, 1.00E+16, 1.00E+17, 1.00E+18, 1.00E+19, 1.00E+20, 1.00E+21, 1.00E+22, 1.00E+23, 1.00E+24, 1.00E+25, orders of magnitude. In another embodiment, herein the decrease/reduction in resistivity (in unit of (2 m) may be by at least, or about: 1, 1.00E+01, 1.00E+02, 1.00E+03, 1.00E+04, 1.00E+05, 1.00E+06, 1.00E+07, 1.00E+08, 1.00E+09, 1.00E+10, 1.00E+11, 1.00E+12, 1.00E+13, 1.00E+14, 1.00E+15, 1.00E+16, 1.00E+17, 1.00E+18, 1.00E+19, 1.00E+20, 1.00E+21, 1.00E+22, 1.00E+23, 1.00E+24, 1.00E+25, orders of magnitude.

In one embodiment, the electric field is applied when the one or more polymers is below the glass transition temperature of the one or more polymers. In one embodiment, the electric field is applied when the one or more polymers is above the glass transition temperature of the one or more polymers.

In one embodiment, exposure to at least one of: an electric field, a magnetic field, an appropriate temperature or temperature range, and/or a pressure or pressure range, for a period of time (or period of times), for example one or more of a “sufficiently strong electric field”, “sufficiently strong magnetic field”, “sufficiently high temperature” and/or “sufficiently strong pressure, transforms the internal organisation of one or more polymers. For example, one or more polymer chains may aggregate and/or closely align parallel and/or perpendicular to the electric field, magnetic field and/or direction of an application of pressure, or due to the exposure to one or more temperature range. The internal alignment of the polymers and/or portions thereof (for example side chains), is due to a number of factors, including the specific one or more polymers used (including the specific substituents or groups present on the polymer backbone and/or side chains), the strength magnitude of the external stimulus (e.g. electric field, magnetic field. pressure and/or temperature), and/or the time that the one or more polymers are exposed to the stimulus or stimuli. Following exposure to at least one of: the electric field, magnetic field, temperature and/or pressure, the internal arrangement of the one or more polymers may become more ordered. Following exposure to at least one of: the electric field, magnetic field, temperature and/or pressure, the one or more polymers may display a change in physical characteristics, such as an increase in hardness, which may be indicated in methods such as atomic force microscopy. The one or more materials may display increased crystalline characteristics through at least a portion of the one or more materials. The one or more materials may move from an amorphous form or substantially amorphous form to a more crystalline, or substantially crystalline form.

Herein to obtain an electrically conductive polymer material, for example to realise topological conducting across the thickness of an employed polymer film containing electron rich domains, an electrical field, which could either be alternating current (AC) or direct current (DC), may be applied to the film. Herein to obtain an electrically conductive polymer material, for example to realise topological conducting across the thickness of an employed polymer film containing electron rich domains, a magnetic field may be applied to the film. Herein to obtain an electrically conductive polymer material, for example to realise topological conducting across the thickness of an employed polymer film containing electron rich domains, an appropriate pressure (e.g. mechanical pressure), may be applied to the film. Herein to obtain an electrically conductive polymer material, for example to realise topological conducting across the thickness of an employed polymer film containing electron rich domains, an appropriate temperature or range of temperatures may be applied to the film. The electron rich domains may subsequently move in parallel with the applied electrical field, magnetic field, direction of application of pressure. Such movement or movement tendency may result in enhanced dangling/stretching degrees of the involved covalent bonds and the accumulations of the polymer chains containing the electron rich domains. As shown in FIG. 1 using a polymer EVA as an example model, the figures demonstrate the realignment of the vinyl acetate (VA) parts in ethylene vinyl acetate (EVA) thin films (5 μm) when placed in electrical fields. Untreated EVA films hosts randomly arranged polymer chains. After placing them in 1 V/um electrical field for 5 seconds, the VA chains accumulated. And the VA chains arrange into order arrays after being treated under in 2 V/um electrical field. Such accumulation/arrangement of VA parts (containing C═O electron rich domains) under suitable electrical field occur throughout the whole depth of the thin films and result in the formation of many pathways for electron transport. Thus, the EVA films become conducive across its thickness.

In another embodiment, the PMMA/PVA polymer can achieve a resistance less than 2 Ohm when made into a thin film without any electrical field larger than 0.1 V/μm

In one embodiment, following the application of an electric field, magnetic field, pressure and/or temperature, to the one or more polymers increases the electrical conductivity of the one or more polymers. In one embodiment the increase in the electrical conductivity is temporary. Following the increase in electrical conductivity, the electrical conductivity may reduce over a period of time, or the electrical conductivity may stay the same or substantially the same in the absence of any further changes, for example the application of a stimulus that chance the electrical, chemical and/or physical properties of the one or more polymers, or an article to which the one or more polymers are disposed and/or attached to in some manner. In one embodiment, the increase in the electrical conductivity is temporally relatively stable and the increase in electrical conductivity is observed to persist, for example over a period of minutes, hours, days, weeks and/or months. In one embodiment the increase in the electrical conductivity is temporary and the electrical conductivity decreases, for example over a period of minutes, hours, days, weeks and/or months.

Herein, the increase in any electrical conductivity may be reversible. The increase in any electrical conductivity may be partially reversible. For example, a change may be made to the one or more polymers after exposure to an electric field, magnetic field, pressure and/or temperature (which may be due to a change in environment, such as temperature), may reduce the conductivity. The reduction in conductivity may revert the electrical conductivity of a material to an original state, or an alternative state. For example, the one or more polymers may be heated, for example via thermal annealing and/or by cooling, such as ultra-cooling. In one embodiment the electrical conductivity of the one or more polymers may be reduced due to a change to the electrical, chemical and/or physical properties of the one or more polymers.

Herein the electrically conductive polymer material may be in the form of a “topological” conducting film. The topological conducting film may be conductive in a single direction, for example a vertical direction.

Insulators may have high values of electrical resistivity in the range of 10¹⁰ Ωm or more.

### Polymers

Herein, for the materials, methods and uses described herein, the selection of polymers may provide one or more of the following advantages:
no chemical curing reaction required
high or low viscosity
conditionally solvent resistant
short process times
unlimited shelf or storage life
materials are weldable
high energy absorption in case of damage
good recycling properties
chemical curing reaction
low viscosity
good fiber impregnation
high solvent resistance
medium-to-long process times
limited shelf or storage life and/or
low fixture effort.

Herein, the one or more polymers, may be selected from, but not limited to: a thermoplastic, a thermoset, and mixtures thereof.

Herein, one or more polymers (or optionally monomers, oligomers), may comprise one or more electron rich domains. The electron rich domains may be present in a polymer backbone, one or more side chains, or a mixture thereof.

The electron rich domains may be groups of covalent bonds comprising a plurality of electron pairs or inorganic atoms with flexible electrons.

Herein, one or more electron rich domains may be selected from, but not limited to: one or more optionally substituted: double bonds, cyclic groups, heterocyclic rings (for example pyrrole rings), aryl rings, heteroaryl rings (for example pyridine rings), fluorine or fluorine containing groups, cyano groups, carbonyls, imines, aldehydes, hydroxyls, esters, carboxylic acids, glycidyl groups, amines, imines, or atoms with free electrons, such as Li, Cu, Fe, Si, S, F, Br, and mixtures thereof.

The one or more polymers, polymer material, or electrically conductive polymer material, may take any form known in the art. Examples include, but are not limited to: linear, branched, hyperbranched, dendrimer, or comb materials, or a mixture thereof. The polymer may be based on a single monomer (for example a homopolymer), or a plurality of different monomers (for example a copolymer such as a statistical, alternating, gradient or block copolymers). The one or more polymers, polymer material, or electrically conductive polymer material, may be composed of any monomer known in the art, for example: styrenics, polyolefins, poly(meth)acrylates, poly(meth)acrylamides, polyethers, silicones, polyesters, polyurethanes, and mixtures thereof.

The one or more polymers, polymer material, or electrically conductive polymer material, may be in any suitable form. The one or more polymers, polymer material, or electrically conductive polymer material, may be in the form of layers and/or sheets and/or particles. The shape and/or size may be adapted dependent on a number of factors. These factors may include the final application, or an article in which the one or more polymers, polymer material, or electrically conductive polymer material, are introduced and/or applied to, and the specific polymers and/or monomers that are selected.

Herein the one or more polymers, polymer material, or electrically conductive polymer material, may comprise one or more polymers selected from, but not limited to: poly(ethylene-vinyl acetate), poly(methyl methacrylate), poly(lactic acid), poly(acrylonitrile butadiene styrene), Nafion, a nylon, Nylon 6, Nylon 6-6, a polyamide, polybutylene terephthalate, a polycarbonate, a polyetheretherketone, a polyetherketoneketone, a polyetherketone, a polyketone, polyethylene terephthalate, a polyimide, a polyoxymethylene plastic, a polyphenylene sulfide, a polyphenylene oxide, a polysulphone, a polyester resin, an epoxy resin, and mixtures thereof.

In one embodiment, the one or more polymers, polymer material, or electrically conductive polymer material, comprise or consist essentially of one or more homopolymers. In another embodiment, the one or more polymers comprise or consist essentially of one or more copolymers. In yet another embodiment, the one or more polymers, polymer material, or electrically conductive polymer material, comprise or consist essentially of one or more copolymers, wherein one or more of the copolymers are derived from, or at least 2, 3 or 4 monomer groups.

The one or more polymers, polymer material, or electrically conductive polymer material, or oligomer may comprise one or more different monomers. Herein, at least one monomer may be selected from, but not limited to: methacrylate-based, acrylate-based, olefin-based, carbonate-based, acrylamide-based, methacrylamide-based, styrene-based, or epoxide-based monomers, or a mixture thereof. For example, at least one monomer may be selected from, but not limited to: methyl acrylate, ethyl acrylate, n-propyl acrylate, isopropyl acrylate, n-butyl acrylate, isobutyl acrylate, sec-butyl acrylate, tert-butyl acrylate, amyl acrylate, hexyl acrylate, 2-ethylhexyl acrylate, octyl acrylate, tert-octyl acrylate, 2-chloroethyl acrylate, 2-bromoethyl acrylate, 4-chlorobutyl acrylate, cyanoethyl acrylate, 2-acetoxyethyl acrylate, dimethylaminoethyl acrylate, benzyl acrylate, methoxybenzyl acrylate, 2-chlorocyclohexyl acrylate, cyclohexyl acrylate, furfuryl acrylate, tetrahydrofurfuryl acrylate, phenyl acrylate, 5-hydroxypentyl acrylate, 2-methoxyethyl acrylate, 3-methoxybutyl acrylate, 2-ethoxybutyl acrylate, 2-ethoxyethyl acrylate, 2-isopropoxy acrylate, 2-butoxyethyl acrylate, 2-(2-methoxyethoxy)ethyl acrylate, 2-(2-methoxyethoxy)ethyl acrylate, 2-(2-butoxyethoxy) ethyl acrylate, ω-methoxypolyethylene glycol acrylate, 1-bromo-2-methoxyethyl acrylate, and 1,1-dichloro-2-ethoxyethyl acrylate; methacrylic esters, optionally: methyl methacrylate, ethyl methacrylate, n-propyl methacrylate, isopropyl methacrylate, n-butyl methacrylate, isobutyl methacrylate, sec-butylmethacrylate, tert-butylmethacrylate, amylmethacrylate, hexylmethacrylate, cyclohexylmethacrylate, benzyl methacrylate, chlorobenzyl methacrylate, octyl methacrylate, stearylmethacrylate, sulfopropylmethacrylate, N-ethyl-N-phenylaminoethyl methacrylate, 2-(3-phenylpropyloxy)ethyl methacrylate, dimethylaminophenoxyethyl methacrylate, furfuryl methacrylate, tetrahydrofurfuryl methacrylate, phenyl methacrylate, cresyl methacrylate, naphthyl methacrylate, 2-hydroxyethyl methacrylate, 4-hydroxybutyl methacrylate, triethylene glycol monomethacrylate, dipropylene glycol monomethacrylate, 2-methoxyethyl methacrylate, 3-methoxybutyl methacrylate, 2-acetoxyethyl methacrylate, 2-acetoacetoxyethyl methacrylate, 2-ethoxyethyl methacrylate, 2-isopropoxyethyl methacrylate, 2-butoxyethyl methacrylate, 2-(2-methoxyethoxy)ethyl methacrylate, 2-(2-ethoxyethoxy)ethyl methacrylate, 2-(2-butoxyethoxy)ethyl methacrylate, ω-methoxypolyethylene glycol methacrylate, acryl methacrylate, and methacrylic acid dimethylaminoethylmethyl chloride salt; vinylesters, optionally: vinylacetate, vinyl propionate, vinyl butyrate, vinyl isobutyrate, vinyl caproate, vinyl chloroacetate, vinylmethoxy acetate, vinylphenyl acetate, vinyl benzoate and vinyl salicylate; acrylamides, optionally: acrylamide, ethylacrylamide, propylacrylamide, isopropylacrylamide, n-butylacrylamide, sec-butylacrylamide, tert-butylacrylamide, cyclohexylacrylamide, benzylacrylamide, hydroxymethylacrylamide, methoxyethylacrylamide, dimethylaminoethylacrylamide, phenylacrylamide, dimethylacrylamide, diethylacrylamide, β-cyanoethylacrylamide, N-(2-acetoacetoxyethyl)acrylamide, and diacetoneacrylamide; methacrylamides, optionally: methacrylamide, methylmethacrylamide, ethylmethacrylamide, propylmethacrylamide, isopropylmethacrylamide, n-butylmethacrylamide, sec-butylmethacrylamide, tert-butylmethacrylamide, cyclohexylmethacrylamide, benzylmethacrylamide, hydroxymethacrylamide, chlorobenzylmethacrylamide, octylmethacrylamide, stearylmethacrylamide, sulfopropylmethacrylamide, N-ethyl-N-phenylaminoethylmethacrylamide, 2-(3-phenylpropyloxy)ethylmethacrylamide, dimethylaminophenoxyethylmethacrylamide, furfurylmethacrylamide, tetrahydrofurfurylmethacrylamide, phenylmethacrylamide, cresylmethacrylamide, naphthylmethacrylamide, 2-hydroxyethylmethacrylamide, 4-hydroxybutylmethacrylamide, triethylene glycol monomethacrylamide, dipropylene glycol monomethacrylamide, 2-methoxyethylmethacrylamide, 3-methoxybutylmethacrylamide, 2-acetoxyethylmethacrylamide, 2-acetoacetoxyethylmethacrylamide, 2-ethoxyethylmethacrylamide, 2-isopropoxyethylmethacrylamide, 2-butoxyethylmethacrylamide, 2-(2-methoxyethoxy) ethylmethacrylamide, 2-(2-ethoxyethoxy)ethylmethacrylamide, 2-(2-butoxyethoxy)ethylmethacrylamide, ω-methoxypolyethylene glycol methacrylamide, acrylmethacrylamide, dimethylaminomethacrylamide, diethylaminomethacrylamide, cyanoethylmethacrylamide, and N-(2-acetoacetoxyethyl)methacrylamide; olefins, optionally: dicyclopentadiene, ethylene, propylene, 1-butene, 1-pentene, vinyl chloride, vinylidene chloride, isoprene, chloroprene, butadiene, and 2,3-dimethylbutadiene; styrenes, optionally: styrene, methylstyrene, dimethylstyrene, trimethylstyrene, ethylstyrene, isopropylstyrene, chloromethylstyrene, methoxystyrene, acetoxystyrene, chlorostyrene, dichlorostyrene, bromostyrene, and vinylbenzoic acid methyl ester; vinyl ethers, optionally: methylvinyl ether, butylvinyl ether, hexylvinyl ether, methoxyethylvinyl ether and dimethylaminoethylvinyl ether; butyl crotonate; hexyl crotonate; dibutyl itaconate; dimethyl maleate; dibutyl maleate; dimethyl fumarate; dibutyl fumarate; methyl vinyl ketone; phenyl vinyl ketone; methoxyethyl vinyl ketone; glycidyl acrylate; glycidyl methacrylate; N-vinyloxazolidone; N-vinylpyrrolidone; acrylonitrile; methacrylonitrile; methylene moronnitrile; vinylidene; and mixtures thereof. In one embodiment, one or more monomers may be selected from: ethylene, butylene, vinyl acetate, methyl methacrylate, lactic acid, butadiene, acrylonitrile, styrene, tetrafluoroethylene, terephthalate, cyclic groups, heterocyclic groups, aryl groups, heteroaryl groups (optionally comprising one or more N, O and/or S atoms), and mixtures thereof.

In one embodiment the one or more polymers, oligomers polymer material, or electrically conductive polymer material, comprise polymers derived from monomers selected from: ethylene, butylene, vinyl acetate, methyl methacrylate, lactic acid, butadiene, acrylonitrile, styrene, tetrafluoroethylene, terephthalate, cyclic groups, heterocyclic groups, aryl groups, heteroaryl groups (optionally comprising one or more N, O and/or S atoms), and mixtures thereof.

In one embodiment the one or more polymers, polymer material, or electrically conductive polymer material, comprise polymers comprising metal and/or non-metal elements.

In one embodiment, one or more polymers, polymer material, or electrically conductive polymer material, further comprise an additive, optionally selected from any components that can adjust the optical and/or mechanical properties for the selected polymer material, such as one or more additives for changing the colour and/or fibres to potentially strengthen the one or more polymers, and mixtures thereof. In another embodiment, the one or more polymers, polymer material, or electrically conductive polymer material comprise no or substantially no further materials and/or additives.

As a variety of different monomers and/or polymers may be used, the material selection allows for a person skilled in the art to tailor the selection to provide one or more favourable or advantageous attributes, for example one or more mechanical, electrical and/or chemical attributes.

In one embodiment, one or more polymers, for example one or more insulating polymers following application of at least one of: an electric field, a magnetic field, a temperature and/or pressure, may have an electrical resistivity of, about, at least, or less than: 1×10⁷ Ωm.

In one embodiment, one or more polymers, for example one or more insulating polymers, following application of at least one of: an electric field, a magnetic field, a temperature and/or pressure, have an electrical conductivity of, about, at least, or more than: 1×10⁻⁷ S/m.

The one or more polymers, polymer material, or electrically conductive polymer material may be a mixture of one or more polymers. The one or more polymers, polymer material, or electrically conductive polymer material, may comprise a mixture wherein one or more of the polymers are mixed in a manner that avoids separation of one or more of the polymers. Alternatively the one or more polymers may be arranged in a manner that allows for separation, for example one or more polymers are provided in a stack of discrete polymers.

The thickness of the one or more polymers, may vary, and the thickness of each polymer may be the same and/or different. Herein the one or more polymers, polymer material, or electrically conductive polymer material, individually and/or collectively, may have a thickness which is on the scale of micrometres, millimetres, centimetres, and/or metres.

In one embodiment, the one or more polymers, polymer material, or electrically conductive polymer material, comprises no or substantially no particles. For example, no or substantially no particles comprising a metal.

Herein the one or more polymers, polymer material, or electrically conductive polymer material may be synthesised and/or fabricated by an appropriate method in the art.

Appropriate methods includes, but are not limited to: hot pressing, drop casting and optional press, spin coating, spray coating, blade coating, sputtering, thermal evaporation, chemical vapour deposition, atomic layer deposition, electrochemical deposition, electron beam deposition, Langmuir-Blodgett deposition, and colloidal deposition, and mixtures thereof.

### Other Materials

Herein one or more polymers, polymer material, or electrically conductive polymer material described herein, may be used with other materials, for example materials such as, but not limited to: one or more metals, one or more semiconductors, one or more materials capable conducting a charge, and mixtures thereof.

The one or more polymers, polymer material, or electrically conductive polymer material, may be disposed between a plurality of materials, for example as an intervening layer and/or connecting layer between two other materials and/or layers.

Herein the one or metals may be selected from, but not limited to: silver, copper, gold, aluminium, molybdenum, zinc, lithium, brass, nickel, steel, palladium, platinum, tungsten, tin, bronze, lead, titanium, steel, iron, and mixtures and/or alloys thereof.

Herein the one or more semiconductors may be selected from, but not limited to: elemental semiconductors non-limiting examples including silicon, gallium, germanium, diamond (carbon), tin, selenium, tellurium, boron, phosphorous, and mixtures thereof; compound semiconductors include ZnSe, GaAs, GaN, InP, InGaAlP, InGaN, SiC, SiGe, and mixtures thereof. The semiconductor can be an i-type semiconductor, a n-type semiconductor or a p-type semiconductor.

Herein, the one or more materials capable of conducting a charge is selected from, but not limited to: carbon-based material, non-limiting examples including activated carbon, carbon nanoparticles, graphite, single walled (SWCNT) or multiwalled (MWCNT) carbon nanotubes, branched carbon nanotubes, carbon nanofiber, graphene, graphene oxide, and mixtures thereof.

Herein, the one or more materials capable of conducting a charge is selected from, but not limited to: conductive polymers, non-limiting examples include where the conductive polymer comprises aromatic cycles, double bonds or a combination thereof. The conductive polymer may be selected from polymers where no heteroatoms are present (i.e. only C and H present) or where heteroatoms are present (i.e. atoms other than C and H are also present). Non-limiting examples of conductive polymers include poly(fluorene)s, polyphenylenes, polypyrenes, polyazulenes, polynaphthalenes, poly(acetylene)s, poly(p-phenylene vinylene), poly(pyrrole)s, polycarbazoles, polyindoles, polyazepines, polyanilines, poly(thiophene)s, poly(3,4-ethylenedioxythiophene), poly(p-phenylene sulfide) or combination thereof.

### Device

Disclosed herein is a device comprising one or more polymers, polymer material, or electrically conductive polymer material conductive adhesive, as described herein.

Herein the device may be selected from or used for: tandem solar cells: interconnection layer (for both 2-terminal and 3-terminal configurations), perovskite/organic solar cells, electrode materials in batteries, organic thin-film transistors for displays and circuits, organic light-emitting diodes (OLEDs) for display and lighting, bioelectronics, surgical devices and cell biology.

In one embodiment, a device described herein comprises a conductive adhesive, as defined herein wherein the conductive adhesive is optionally a transparent conductive adhesive.

Also disclosed herein is a photovoltaic power generating device comprising the polymer material, or the electrically conductive polymer material as described herein as a conductive layer (e.g. a layer that can effectively transfer carriers from one side to the other) and/or intermediate layer. the intermediate layer may be used as an adhesive and/or boding layer. In one embodiment, the photovoltaic power generating device of claim comprises, consists essentially of or consists of tandem solar cells comprising the polymer material, or the electrically conductive polymer material as described herein. In another embodiment, the polymer material, or the electrically conductive polymer material, is present as at least one intermediate layer.

Also disclosed herein is use of the polymer material, or the electrically conductive polymer material as described herein forming at least a portion of a device selected from, but not limited to: a battery, an organic thin-film transistor, an organic light-emitting diodes (OLEDs), a bioelectronics device and/or a surgical device.

Also disclosed herein is a device comprising: a first layer; a second layer; and a third layer, wherein:
the third layer is arranged between the first and second layers and
the third layer comprising one or more polymers, polymer material, or electrically conductive polymer material, as defined herein.

Herein, the device may further comprise: a top photovoltaic cell; and a bottom photovoltaic cell, wherein:
the first layer is arranged between the top photovoltaic cell and the third layer, and
the second layer is arranged between the bottom photovoltaic cell and the third layer.

In another embodiment, a surface of the photovoltaic cell in contact with the third layer is textured.

In one embodiment, the third layer is configured to provide no electrical conductivity along a direction parallel to the plane of the third layer.

In another embodiment, at least one of the first layer or the second layer comprises a semiconductor as defined herein.

In another embodiment, at least one of the first layer or the second layer comprises a metal as defined herein.

In another embodiment, at least one of the first layer or the second layer comprises a conducting adhesive optionally a transparent conducting adhesive.

In another embodiment, the first layer is a semiconductor substrate and the second layer is a silicon substrate. In yet another embodiment, a surface of the silicon substrate in contact with the third layer is textured.

In yet another embodiment, the first layer is a photovoltaic cell, and the second layer is a back sheet comprising a first area of patterned conductors. The back sheet may further comprise a second area that is transparent to solar radiation.

### EXAMPLE EMBODIMENTS

The present disclosure may be defined by one or more example embodiments.
1. A polymer material comprising one or more polymers (or optionally monomers and/or oligomers), optionally one or more insulating polymers or one or more conductive polymers, comprising one or more electron rich domains, wherein when:
   a sufficiently strong electric field is applied across the one or more polymers and/or
   a sufficiently strong magnetic field is applied across the one or more polymers; and/or
   a sufficiently high temperature is applied across the one or more polymers; and/or
   a sufficiently strong pressure is applied across the one or more polymers,
      the electrical conductivity of the polymer material is increased.
2. A polymer material comprising one or more polymers (or optionally monomers and/or oligomers), optionally one or more insulating polymers or one or more conductive polymers, comprising one or more electron rich domains, wherein when:
   the polymer material is disposed between a plurality of layers, each layer independently selected from: one or more metals, one or more semiconductors, one or more materials capable conducting a charge, and mixtures thereof; and
   at least one of:
      a sufficiently strong electric field is applied across the one or more polymers; and/or
      a sufficiently strong magnetic field is applied across the one or more polymers; and/or
      a sufficiently high temperature is applied across the one or more polymers; and/or
      a sufficiently strong pressure is applied across the one or more polymers,
         the electrical conductivity of the polymer material is increased.
3. An electrically conductive polymer material formed from the polymer material of example embodiment 1 or example embodiment 2, wherein the one or more polymers (or optionally monomers and/or oligomers), optionally one or more insulating polymers, are exposed to at least one of: the sufficiently strong electric field, the sufficiently strong magnetic field, the sufficiently high temperature and/or the sufficiently strong pressure.
4. The electrically conductive polymer material of example embodiment 3, wherein the conductive polymer material is a conductive adhesive.
5. The electrically conductive polymer material of example embodiment 3, wherein the conductive polymer material is a transparent conductive adhesive.
6. A method of producing an electrically conductive polymer material, the method comprising applying at least one of:
   a sufficiently strong electric field; and/or
   a sufficiently strong magnetic field; and or
   a sufficiently high temperature; and/or
   a sufficiently strong pressure,
      across one or more polymers (optionally one or more insulating polymers), comprising one or more electron rich domains, wherein the electrical conductivity of the one or more polymers (or optionally monomers and/or oligomers), is increased.
7. A method of improving the electrical conductivity of a polymer material comprising one or more polymers (or optionally monomers and/or oligomers), the method comprising applying at least one of:
   a sufficiently strong electric field; and/or
   a sufficiently strong magnetic field; and/or
   a sufficiently high temperature; and/or
   a sufficiently strong pressure,
      across the one or more polymers comprising one or more electron rich domains, wherein the electrical conductivity of the conductive polymer material is increased.
8. A method of producing an electrically conductive polymer material, the method comprising:
   disposing one or more polymers (or optionally monomers and/or oligomers), optionally one or more insulating polymers, comprising one or more electron rich domains between a plurality of layers, each layer independently selected from: one or more metals, one or more semiconductors, one or more materials capable conducting a charge, and mixtures thereof; and
   applying at least one of:
      a sufficiently strong electric field; and/or
      a sufficiently strong magnetic field; and/or
      a sufficiently high temperature and/or
      a sufficiently strong pressure,
         across the one or more polymers, wherein the electrical conductivity of the one or more polymers (or optionally monomers and/or oligomers) is increased.
9. Use of one or more polymers (optionally one or more insulating polymers), comprising one or more electron rich domains, in a polymer material, to produce an electrically conductive polymer, wherein when at least one of:
   a sufficiently strong electric field; and/or
   a sufficiently strong magnetic field; and/or
   a sufficiently high temperature; and/or
   a sufficiently strong pressure,
      is applied across the one or more polymers (or optionally monomers and/or oligomers), the electrical conductivity of the polymer material is increased.
10. The method or use of any one of example embodiment 6 to 9, wherein the electrically conductive polymer material is a conductive adhesive, or a transparent conductive adhesive.
11. Use of one or more polymers (or optionally monomers and/or oligomers), optionally one or more insulating polymers, for physically and electronically connecting a plurality of layers, each layer independently selected from: one or more metals, one or more semiconductors, one or more materials capable conducting a charge, and mixtures thereof, wherein when:
   the one or more polymers are disposed between the plurality of layers and
   at least one of:
      a sufficiently strong electric field; and/or
      a sufficiently strong magnetic field; and/or
      a sufficiently high temperature; and/or
      a sufficiently strong pressure,
   is applied across the one or more polymers,
      the electrical conductivity of the one or more polymers (or optionally monomers and/or oligomers) is increased.
12. The polymer material, electrically conductive polymer material, method, or use, of any one of the preceding example embodiments, wherein the electric field has a strength of at least 10, 20, 30, 40, 50, 60, 70, 80, 90, or 100 V/m.
13. The polymer material, electrically conductive polymer material, method, or use, of any one of the preceding example embodiments, wherein the one or more polymers (or optionally monomers and/or oligomers) comprise the one or more electron rich domains present in a polymer backbone and/or sidechain.
14. The polymer material, electrically conductive polymer material, method, or use, of any one of the preceding example embodiments, wherein the one or more polymers (or optionally monomers and/or oligomers) comprise one or more electron rich domains selected from one or more optionally substituted: double bonds, cyclic groups, heterocyclic rings, aryl rings, heteroaryl rings, fluorine or fluorine containing groups, cyano groups, carbonyls, aldehydes, hydroxyls, esters, carboxylic acids, glycidyl groups, amines, imines, or atoms with unbonded electrons, optionally selected from Li, Cu, Fe, Si, S, O, F, Br, and mixtures thereof.
15. The polymer material, electrically conductive polymer material, method, or use, of any one of the preceding example embodiments, wherein the one or more polymers comprise one or more polymers selected from: poly(ethylene-vinyl acetate), poly(methyl methacrylate), polylactic acid, poly(acrylonitrile butadiene styrene), Nafion, a nylon, Nylon 6, Nylon 6-6, a polyamide, polybutylene terephthalate, a polycarbonate, a polyetheretherketone, a polyetherketoneketone, a polyetherketone, a polyketone, polyethylene terephthalate (pet), a polyimide, a polyoxymethylene plastic, a polyphenylene sulfide, a polyphenylene oxide, a polysulphone, a polyester resin, an epoxy resin, and mixtures thereof.
16. The polymer material, electrically conductive polymer material, method, or use, of any one of the preceding example embodiments, wherein the one or more polymers comprises or consists essentially of one or more homopolymers, copolymers, or a mixture thereof.
17. The polymer material, electrically conductive polymer material, method, or use, of any one of the preceding example embodiments, wherein the one or more polymers comprise or consist essentially of one or more homopolymers.
18. The polymer material, electrically conductive polymer material, method, or use, of any one of the preceding example embodiments, wherein the one or more polymers comprise or consist essentially of one or more copolymers.
19. The polymer material, electrically conductive polymer material, method, or use, of any one of the preceding example embodiments, wherein the one or more polymers comprise or consist essentially of one or more copolymers, wherein one or more of the copolymers are derived from or at least 2, 3 or 4 monomer groups.
20. The polymer material, electrically conductive polymer material, method, or use, of any one of the preceding example embodiments, wherein the one or more polymers comprise polymers derived from monomers selected from, or the monomer or oligomer is selected or based on: methyl acrylate, ethyl acrylate, n-propyl acrylate, isopropyl acrylate, n-butyl acrylate, isobutyl acrylate, sec-butyl acrylate, tert-butyl acrylate, amyl acrylate, hexyl acrylate, 2-ethylhexyl acrylate, octyl acrylate, tert-octyl acrylate, 2-chloroethyl acrylate, 2-bromoethyl acrylate, 4-chlorobutyl acrylate, cyanoethyl acrylate, 2-acetoxyethyl acrylate, dimethylaminoethyl acrylate, benzyl acrylate, methoxybenzyl acrylate, 2-chlorocyclohexyl acrylate, cyclohexyl acrylate, furfuryl acrylate, tetrahydrofurfuryl acrylate, phenyl acrylate, 5-hydroxypentyl acrylate, 2-methoxyethyl acrylate, 3-methoxybutyl acrylate, 2-ethoxybutyl acrylate, 2-ethoxyethyl acrylate, 2-isopropoxy acrylate, 2-butoxyethyl acrylate, 2-(2-methoxyethoxy)ethyl acrylate, 2-(2-methoxyethoxy)ethyl acrylate, 2-(2-butoxyethoxy)ethyl acrylate, ω-methoxypolyethylene glycol acrylate, 1-bromo-2-methoxyethyl acrylate, and 1,1-dichloro-2-ethoxyethyl acrylate; methacrylic esters, optionally: methyl methacrylate, ethyl methacrylate, n-propyl methacrylate, isopropyl methacrylate, n-butyl methacrylate, isobutyl methacrylate, sec-butylmethacrylate, tert-butylmethacrylate, amylmethacrylate, hexylmethacrylate, cyclohexylmethacrylate, benzyl methacrylate, chlorobenzyl methacrylate, octyl methacrylate, stearylmethacrylate, sulfopropylmethacrylate, N-ethyl-N-phenylaminoethyl methacrylate, 2-(3-phenylpropyloxy)ethyl methacrylate, dimethylaminophenoxyethyl methacrylate, furfuryl methacrylate, tetrahydrofurfuryl methacrylate, phenyl methacrylate, cresyl methacrylate, naphthyl methacrylate, 2-hydroxyethyl methacrylate, 4-hydroxybutyl methacrylate, triethylene glycol monomethacrylate, dipropylene glycol monomethacrylate, 2-methoxyethyl methacrylate, 3-methoxybutyl methacrylate, 2-acetoxyethyl methacrylate, 2-acetoacetoxyethyl methacrylate, 2-ethoxyethyl methacrylate, 2-isopropoxyethyl methacrylate, 2-butoxyethyl methacrylate, 2-(2-methoxyethoxy)ethyl methacrylate, 2-(2-ethoxyethoxy)ethyl methacrylate, 2-(2-butoxyethoxy)ethyl methacrylate, ω-methoxypolyethylene glycol methacrylate, acryl methacrylate, and methacrylic acid dimethylaminoethylmethyl chloride salt; vinylesters, optionally: vinylacetate, vinyl propionate, vinyl butyrate, vinyl isobutyrate, vinyl caproate, vinyl chloroacetate, vinylmethoxy acetate, vinylphenyl acetate, vinyl benzoate and vinyl salicylate; acrylamides, optionally: acrylamide, ethylacrylamide, propylacrylamide, isopropylacrylamide, n-butylacrylamide, sec-butylacrylamide, tert-butylacrylamide, cyclohexylacrylamide, benzylacrylamide, hydroxymethylacrylamide, methoxyethylacrylamide, dimethylaminoethylacrylamide, phenylacrylamide, dimethylacrylamide, diethylacrylamide, β-cyanoethylacrylamide, N-(2-acetoacetoxyethyl)acrylamide, and diacetoneacrylamide; methacrylamides, optionally: methacrylamide, methylmethacrylamide, ethylmethacrylamide, propylmethacrylamide, isopropylmethacrylamide, n-butylmethacrylamide, sec-butylmethacrylamide, tert-butylmethacrylamide, cyclohexylmethacrylamide, benzylmethacrylamide, hydroxymethacrylamide, chlorobenzylmethacrylamide, octylmethacrylamide, stearylmethacrylamide, sulfopropylmethacrylamide, N-ethyl-N-phenylaminoethylmethacrylamide, 2-(3-phenylpropyloxy)ethylmethacrylamide, dimethylaminophenoxyethylmethacrylamide, furfurylmethacrylamide, tetrahydrofurfurylmethacrylamide, phenylmethacrylamide, cresylmethacrylamide, naphthylmethacrylamide, 2-hydroxyethylmethacrylamide, 4-hydroxybutylmethacrylamide, triethylene glycol monomethacrylamide, dipropylene glycol monomethacrylamide, 2-methoxyethylmethacrylamide, 3-methoxybutylmethacrylamide, 2-acetoxyethylmethacrylamide, 2-acetoacetoxyethylmethacrylamide, 2-ethoxyethylmethacrylamide, 2-isopropoxyethylmethacrylamide, 2-butoxyethylmethacrylamide, 2-(2-methoxyethoxy) ethylmethacrylamide, 2-(2-ethoxyethoxy)ethylmethacrylamide, 2-(2-butoxyethoxy)ethylmethacrylamide, ω-methoxypolyethylene glycol methacrylamide, acrylmethacrylamide, dimethylaminomethacrylamide, diethylaminomethacrylamide, cyanoethylmethacrylamide, and N-(2-acetoacetoxyethyl)methacrylamide; olefins, optionally: dicyclopentadiene, ethylene, propylene, 1-butene, 1-pentene, vinyl chloride, vinylidene chloride, isoprene, chloroprene, butadiene, and 2,3-dimethylbutadiene; styrenes, optionally: styrene, methylstyrene, dimethylstyrene, trimethylstyrene, ethylstyrene, isopropylstyrene, chloromethylstyrene, methoxystyrene, acetoxystyrene, chlorostyrene, dichlorostyrene, bromostyrene, and vinylbenzoic acid methyl ester; vinyl ethers, optionally: methylvinyl ether, butylvinyl ether, hexylvinyl ether, methoxyethylvinyl ether and dimethylaminoethylvinyl ether; butyl crotonate; hexyl crotonate; dibutyl itaconate; dimethyl maleate; dibutyl maleate; dimethyl fumarate; dibutyl fumarate; methyl vinyl ketone; phenyl vinyl ketone; methoxyethyl vinyl ketone; glycidyl acrylate; glycidyl methacrylate; N-vinyloxazolidone; N-vinylpyrrolidone; acrylonitrile; methacrylonitrile; methylene moronnitrile; vinylidene; and mixtures thereof.
21. The polymer material, electrically conductive polymer material, method, or use, of any one of the preceding example embodiments, wherein the one or more polymers comprise polymers derived from monomers selected from, or the monomer is selected from, or the oligomer comprises: ethylene, butylene, vinyl acetate, methyl methacrylate, lactic acid, butadiene, acrylonitrile, styrene, tetrafluoroethylene, terephthalate, cyclic groups, heterocyclic groups, aryl groups, heteroaryl groups, optionally comprising one or more N, O and/or S atoms, and mixtures thereof.
22. The polymer material, electrically conductive polymer material, method, or use, of any one of the preceding example embodiments, wherein the one or more polymers comprise one or more intrinsic conductive polymer material, optionally selected from: poly(3,4-ethylenedioxythiophene)polystyrene sulfonate (PEDOT:PSS), poly(3-hexylthiophene) (P3HT), polyacetylene (PA), polyaniline (PANI), polypyrrole (PPy), polythiophene (PTH), poly(para-phenylene) (PPP), poly(phenylenevinylene) (PPV), and polyfuran (PF), and mixtures thereof.
23. The polymer material, electrically conductive polymer material, method, or use, of any one of the preceding example embodiments, wherein the one or more polymers comprise one or more extrinsic conductive polymer material, optionally comprising or consisting of a matrix of polymer with a percentage of conducting material, wherein the conducting material is optionally selected from: metal particles, metal coated particles, indium tin oxide particles, powdered graphite, and mixtures thereof.
24. The polymer material, electrically conductive polymer material, method, or use, of any one of the preceding example embodiments, wherein the one or more polymers are independently fabricated by one or more processes selected from: hot pressing, drop casting and optional press, spin coating, spray coating, blade coating, sputtering, thermal evaporation, chemical vapour deposition, atomic layer deposition, electrochemical deposition, electron beam deposition, Langmuir-Blodgett deposition, and colloidal deposition, and mixtures thereof.
25. The polymer material, electrically conductive polymer material, method, or use, of any one of the preceding example embodiments, wherein the increase in the electrical conductivity is reversible or partially reversible.
26. The polymer material, electrically conductive polymer material, method, or use, of example embodiment any one of the preceding example embodiments, wherein the electrical conductivity is reversible or partially via heat treatment, optionally thermal annealing or cooling, optionally ultra-cooling.
27. A polymer material, or an electrically conductive polymer material obtained from the method according to any one of the preceding example embodiments, wherein the polymer material is optionally a conductive polymer adhesive, optionally a transparent conductive adhesive.
28. A device comprising a polymer material, or an electrically conductive polymer material according to any one of the preceding example embodiments.
29. A device comprising: a first layer; a second layer; and a third layer comprising transparent conductive adhesive, wherein:
   the third layer is arranged between the first and second layers and
   the third layer comprising the polymer material, or the electrically conductive polymer material according to any one of example embodiment 1 to 27.
30. The device according to example embodiment 28 or example embodiment 29, wherein the polymer material, or the electrically conductive polymer material is a conductive adhesive, optionally a transparent conductive adhesive.
31. The device according to example embodiment 28 or example embodiment 29, wherein the third layer is configured to provide no electrical conductivity along a direction parallel to the plane of the third layer.
32. The device according to any one of example embodiment 28 to 31, wherein at least one of the first layer or the second layer comprises a semiconductor.
33. The device according to any one of example embodiment 28 to 32, wherein at least one of the first layer or the second layer comprises a metal.
34. The device according to any one of example embodiment 28 to 33, wherein at least one of the first layer or the second layer comprises a transparent conducting material.
35. The device according to any one of example embodiment 28 to 32, wherein the first layer is a semiconductor substrate and the second layer is a silicon substrate
36. The device according to example embodiment 35, wherein a surface of the silicon substrate in contact with the third layer is textured.
37. The device according to example embodiment 29, further comprising: a top photovoltaic cell; and a bottom photovoltaic cell, wherein:
   the first layer is arranged between the top photovoltaic cell and the third layer, and
   the second layer is arranged between the bottom photovoltaic cell and the third layer.
38. The device according to example embodiment 29, wherein: the first layer is a photovoltaic cell, and the second layer is a back sheet comprising a first area of patterned conductors.
39. The device according to example embodiment 38, wherein the back sheet further comprises a second area that is transparent to solar radiation.
40. A photovoltaic power generating device comprising the polymer material, or the electrically conductive polymer material according to any one of example embodiment 1 to 27 as a conductive layer and/or intermediate layer.
41. The photovoltaic power generating device of example embodiment 41 comprising, consisting essentially of or consisting of tandem solar cells comprising the polymer material, or the electrically conductive polymer material according to any one of example embodiment 1 to 27.
42. The photovoltaic power generating device of example embodiment 41 or example embodiment 42, wherein the polymer material, or the electrically conductive polymer material, is present as at least one intermediate layer.
43. Use of the polymer material, or the electrically conductive polymer material according to any one of example embodiment 1 to 27 in: a battery, an organic thin-film transistor, an organic light-emitting diodes (OLEDs), a bioelectronics device, a surgical device and/or cell biology.

### EXAMPLES

The present disclosure will now be described with reference to the following non-limiting examples and with reference to the accompanying Figures (where relevant).

### Example 1. Experimental Details

Heavily doped Si wafers (2×2 cm²) with back metal contacts were used as substrates to convert the insulating polymer layer into the conductive polymer layer. Selected polymer materials, exemplified here by a commercial epoxy, were prepared according to their standard process recipes and then spin-coated onto polished silicon wafers. Subsequently, another Si wafer (with the polished side facing down) was attached to the epoxy layer. The attached Si wafers were hot-pressed according to the standard curing method of the selected polymer, forming a strong mechanical bonding.

A voltage was subsequently applied to the front and back metal contacts of the Si wafers to carry out an electrical treatment, as shown in FIG. 1. The conductivity of the polymer layer was characterized by monitoring the current using an Advantest direct current (DC) Source Measurement Unit (SMU) with a 2 A current limit.

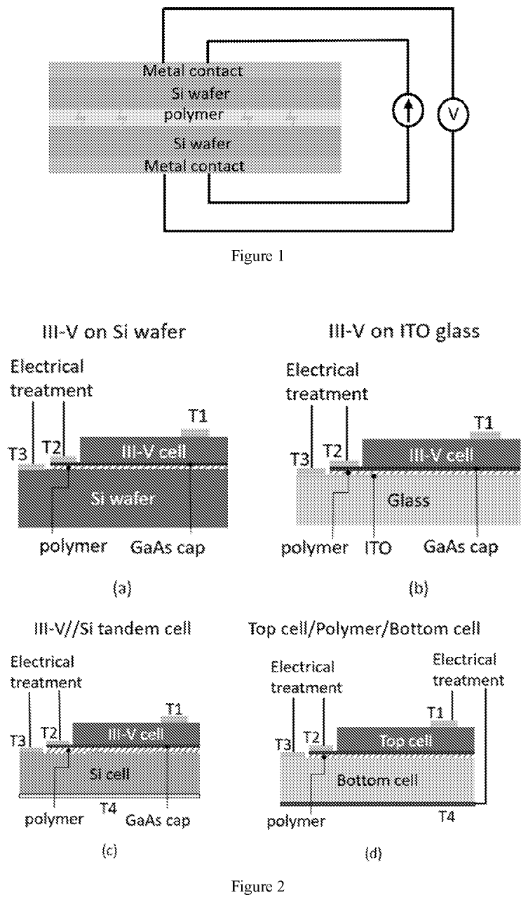

To analyse its performance as an intermediate layer, the polymer film was applied to bond the semitransparent III-V cells onto Si wafer and ITO glass to carry out the electrical and optical characterizations. Then the selected polymer layer was used to bond the semitransparent III-V cells to Si bottom cell for the 2-terminal (2T) III-V//Si tandem cells fabrication. A 200 nm thick Ag layer is evaporated on the rear side of the HIT Si cell as the back metal contact. The GaInP/GaAs double-junction solar cells invertedly grown on GaAs substrates with the size of 1×1 cm² were used as the top cells. The III-V cells were attached to the epoxy-coated substrates, followed by the hot-pressing process described above to cure the epoxy and realize the mechanical bonding. The GaAs substrate was subsequently removed by wet chemical etching to fabricate the III-V device. The edge of the GaInP/GaAs cell was etched to expose the back cap layer for metal contact deposition. Finally, a 200 nm thick Au layer was deposited by e-beam evaporation with a mask to form the metal contacts on the front surface of III-V cell (T1), back cap layer of III-V cell (T2), and the front surface of the bottom substrate (T3). The structures of the completed samples are illustrated in FIG. 2(a)-(c). The electrical treatment is performed through T2 and T3 to produce the conductive polymer layer.

### Example 2. Impact of Electrical Treatment on the Electrical Property of Polymer Layer

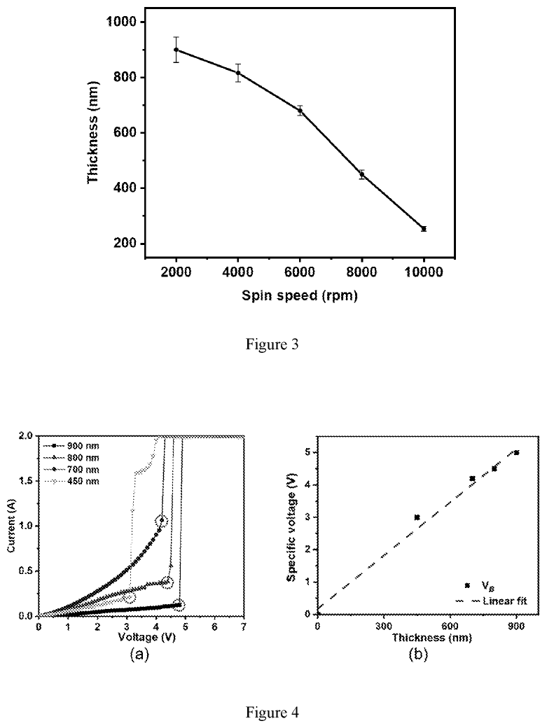

The thickness of the epoxy layers was controlled by varying the spin speed during spin coating and was characterized by cross-sectional Scanning Electron Microscope (SEM) measurement. FIG. 3 shows the dependence of epoxy thickness on spin speed. With the spin speed increasing from 2000 rpm to 10000 rpm, the average thickness of epoxy was decreased from 900 nm to 250 nm. The variation of epoxy thickness was measured to be within the ±5% for each branch of samples, and the standard deviations of different branches of samples are indicated in FIG. 3.

Subsequently, Si/epoxy/Si samples with different epoxy thicknesses of 900 nm, 800 nm, 700 nm, and 450 nm were employed to investigate the electrical treatment voltage. A sweeping voltage from 0 V to 7 V was applied on the samples with the measured IV curves shown in FIG. 4(a). With the increase of the applied voltage, an abrupt jump of current was observed for each sample at a specific voltage (indicated by dashed circles). The specific voltage that induces abrupt current increasing is identified as the voltage V_{B}. FIG. 4(b) shows the dependence of the specific voltage on polymer thickness d. V_{B} increases linearly with d from 3 V for 450 nm epoxy layer to 5 V for 900 nm epoxy layer.

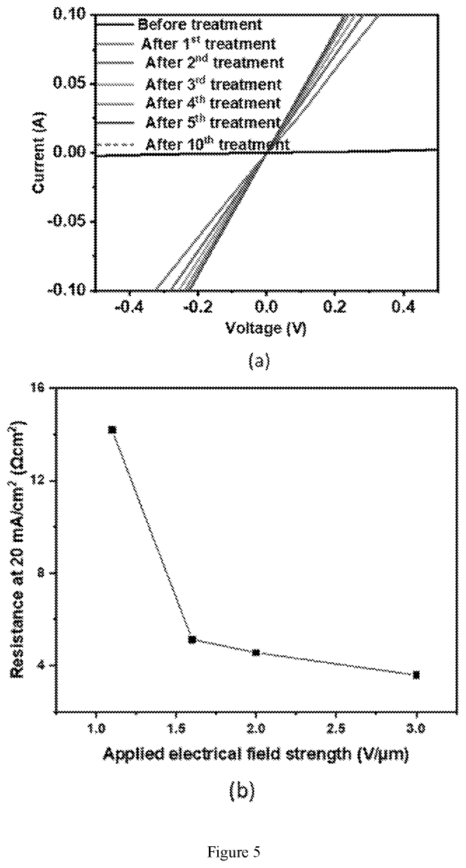

Another selected polymer, exemplified here by ethylene vinyl-acetate (EVA), was applied to bond the Si wafers and the I-V curves of sample were measured after each time of treatment under the electrical field of 3V/μm, as shown in FIG. 5(a). The electrical resistance of the sample drops from >200Ω to 2Ω along with the electrical treatment. Furthermore, the conducting degree (namely, the final resistance achieved) is adjustable by tuning the applied electrical field to the films of certain thickness, which means the conductivity is controllable. FIG. 5(b) shows the resistance of an EVA film is adjusted by using a different electrical field.

### Example 3. Film Characterisation

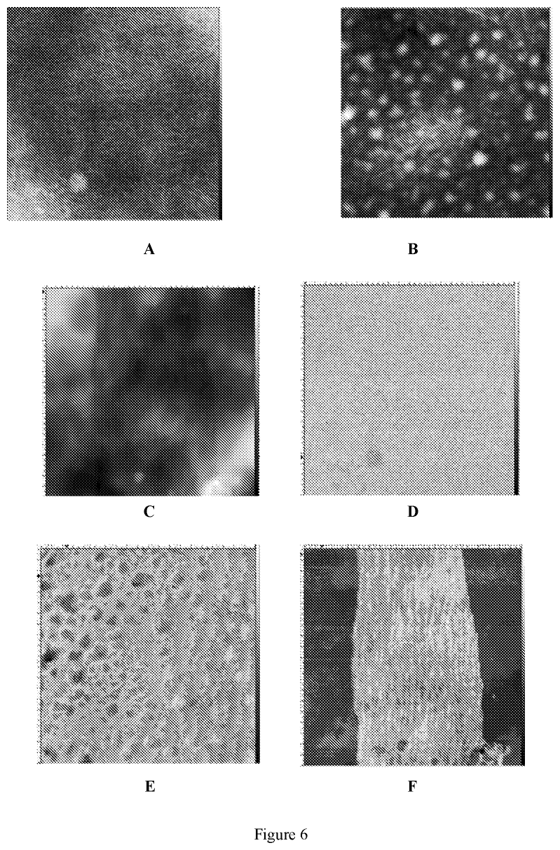

To investigate the mechanism of converting the insulating polymer layer into the conductive layer through electrical treatment, the AFM imaging characterization was conducted on the polymer surface before and after the treatment, as shown in FIG. 6. To realise topological conducting across the thickness of employed polymer film containing electron rich domains, an electrical field was applied to the film. The electron rich domains subsequently moved in parallel with the applied electrical field. Such movement or movement tendency results in enhanced dangling/stretching degrees of the involved covalent bonds and the accumulations of the polymer chains containing the electron rich domains. FIG. 6 demonstrates the realignment of the vinyl acetate (VA) parts in EVA thin films (5 μm) when placed in electrical fields. Untreated EVA films hosts randomly arranged polymer chains. After placing them in 1 V/μm electrical field for 5 seconds, the VA chains accumulated. The VA chains arrange into order arrays after being treated under in 2 V/μm electrical field. Such accumulation/arrangement of VA parts (containing C═O electron rich domains) under suitable electrical field occur throughout the whole depth of the thin films and result in the formation of many pathways for electron transport. Thus, the EVA films become conductive across its thickness.

### Example 4. Impact of Electrical Treatment on the Optical Property of Polymer Layer

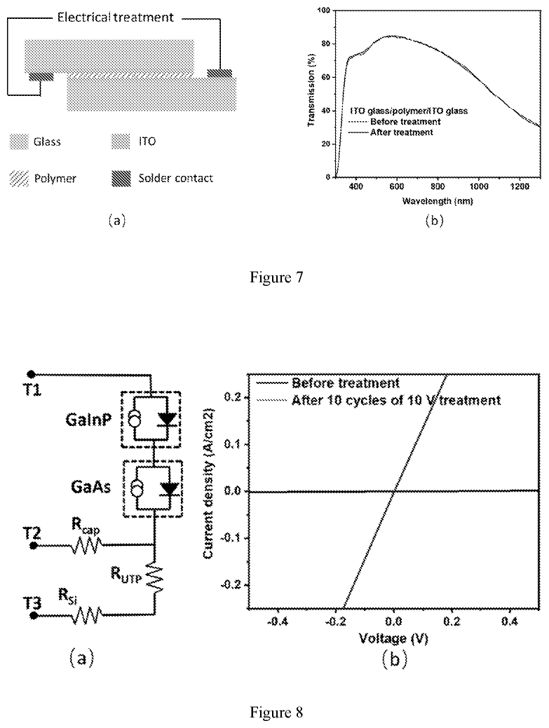

The optical property of the post electrical treatment polymer layer was investigated using the structure illustrated in FIG. 7 (a). Soldered contacts are made in the exposed areas of the ITO to perform the cyclic treatment. FIG. 7 (b) shows the measured transmission of bonded ITO glasses before and after the electrical treatment. The treatment of converting insulating polymer films into conductive materials showed negligible impact on the optical properties of polymer films, as shown in FIG. 7 (b). Therefore, the optical properties (e.g. transmission) of a polymer film are determined by the intrinsic properties of the polymer material applied. Most polymer materials are transparent like glass, and minimal absorption losses of <3% are achievable.

### Example 5. Polymer as the Intermediate Layer

Since polymer layer has demonstrated good electrical and optical properties after electrical treatment, the performance of polymer as an intermediate layer and its impact on III-V cell efficiency is highlighted. III-V top cells are bonded by selected polymer on Si wafer and ITO glass to study its electrical and optical performance, respectively.

### Example 5.1 III-V Cell Bonded on Si Wafer by Polymer Layer

The structure of the III-V cell bonded on Si wafer by polymer layer is shown in FIG. 8(a) with its equivalent circuit shown in FIG. 8(a). A standard cyclic electrical treatment was applied through the metal contacts on the back cap layer of the III-V cell (T2) and the front surface of the Si wafer (T3) to produce a conductive polymer layer. Significant reduction of T2-T3 resistance to 0.75Ω after the standard cyclic electrical treatment was revealed by IV measurement shown in FIG. 8 (b). The T2-T3 resistance is the sum of resistances of the GaAs cap layer (R_{cap}), the Si wafer (R_{Si}), and the polymer layer (Rₚ). Thus, the resistance of the polymer layer was reduced to lower than 0.75 Ω after the cyclic electrical treatment which is well below the resistance threshold of high-quality intermediate layer for efficient tandem cell fabrication.^{[1] [2]}

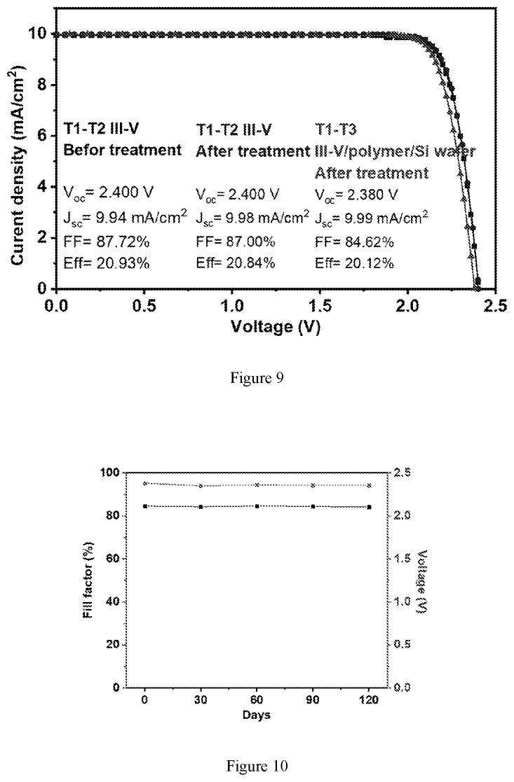

FIG. 9 exhibits the measured JV curves of the III-V cell through different terminals before and after the electrical treatment. The JV curves of III-V cell measured through the metal contacts on the front surface (T1) and back cap layer of III-V cell (T2) before and after electrical treatment are almost identical, indicating that no cell degradation is caused by the electrical treatment. T1-T2 measurement exhibits an efficiency of 20.93%, which is the result without the contribution of R_{P} and R_{Si}. The measurement of cell performance over the polymer layer through metal contact on the front surface of III-V cell (T1) and Si wafer (T3) is subsequently conducted to investigate the impact of the polymer layer resistance. Before the electrical treatment, no current can be collected due to the high resistance of the polymer layer. The JV curve measured through T1-T3 after the electrical treatment is presented by the red curve in FIG. 9. A slight increase in the series resistance compared with the T1-T2 measurement was revealed, which leads to FF dropping from 87.00% to 84.62%. The open-circuit voltage (V_{OC}) and short-circuit current density (J_{SC}) measured through T1-T3 are consistent with that measured through T1-T2. A slightly lower efficiency of 20.12% was obtained through T1-T3 measurement due to the involvement of R_{P}and R_{Si}. The characterisation of III-V cell bonded on Si wafer by polymer layer demonstrates that the cyclic electrical treatment will not damage the III-V cell, and relatively high performance was maintained after incorporating the polymer intermediate layer.

### Example 5.2 Stability

Stability is another important factor in evaluating the performance of the polymer intermediate layer. The stability of bonded III-V cell on Si wafer by polymer layer is investigated by monitoring the cell performance after the electrical treatment. The samples are kept under N₂ atmosphere for 120 days and measured through T1 and T3 every 30 days. As shown in FIG. 10, the FF and V_{OC} are constant after 120 days, with only a subtle decrease of 0.05% in FF and 24.7 mV drop in V_{OC}. These results demonstrate the good stability of the polymer bonding layer.

### Example 5.3 III-V Cell Bonded on ITO Glass by Polymer Layer

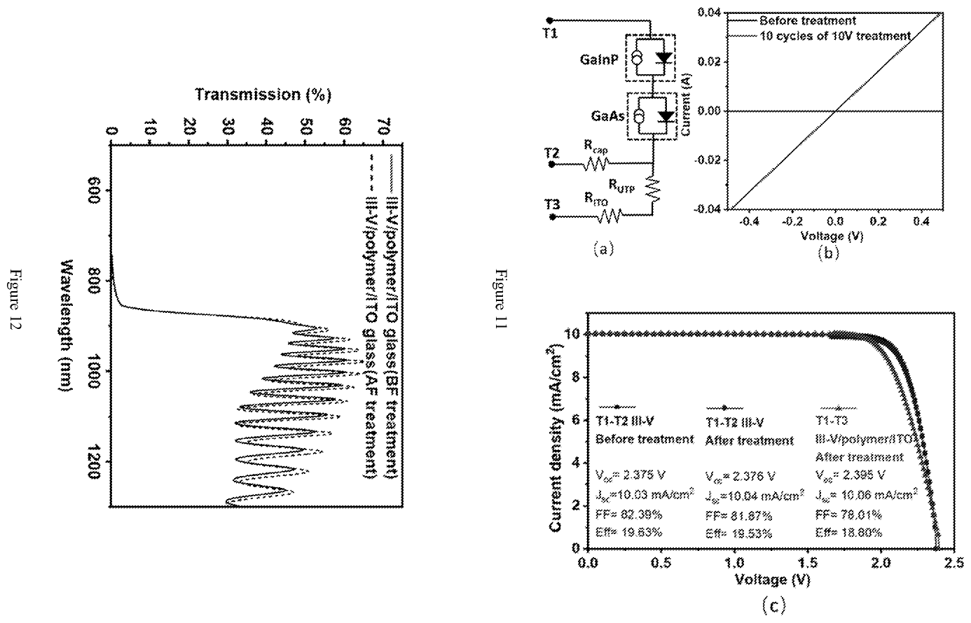

The polymer layer was also used to bond the III-V cell on ITO glass to investigate its optical performance as the intermediate layer. The impact of electrical treatment on long-wavelength transmission was first examined, then an ARC layer is incorporated to enhance the transmission of sub-bandgap light. The structure of the III-V cell bonded on ITO glass is shown in FIG. 2 (b), and its equivalent circuit is presented in FIG. 11(a). After the standard cyclic electrical treatment through the metal contacts on the back cap layer of III-V cell (T2) and ITO glass (T3), the T2-T3 resistance was reduced to 12Ω, indicating that the conductive polymer layer was obtained. T2-T3 resistance is higher than that of the III-V cell bonded on the Si wafer mainly due to the higher lateral sheet resistance of the ITO layer than that of the heavily doped Si wafer. The JV curves of single III-V cell measured through T1-T2 before and after the electrical treatment overlap closely in FIG. 11 FIG. 11(c). The measurement through T1-T3 passing through the polymer layer exhibits a 78.01% FF, which is 3.86% lower than the T1-T2 measurement, mainly due to the lateral sheet resistance of the ITO layer.

The impact of cyclic electrical treatment on the optical property of the polymer layer was examined by measuring the transmission of the III-V cell bonded on ITO glass before and after the electrical treatment. As shown in FIG. 12, no significant change in the transmission is observed after performing the electrical treatment. This result is consistent with the transmission measured on the bonded ITO glasses by polymer layer illustrated in FIG. 7 (b), confirming no optical loss at the long wavelengths induced by the cyclic electrical treatment. Therefore, the bonding by polymer layer offers low resistance without losing transmission, circumventing the conventional trade-off between transparency and conductivity associated with previous composite intermediate layers containing metal conductive particles.^{[3] [4]}

Several conclusions can be drawn from the characterizations of III-V cells bonded on Si wafer and ITO glass by the polymer layer. First, the cyclic electrical treatment will not degrade the III-V cell performance. Second, the electrical treatment does not induce any significant transmission loss of the sub-bandgap light of the III-V cell. These results exhibit the decent performance of the bonding by polymer layer which is promising for the fabrication of efficient 2T III-V//Si tandem solar cells.

### Example 6. Two-Terminal III-V//Si Tandem Solar Cells Bonded by Polymer Layer

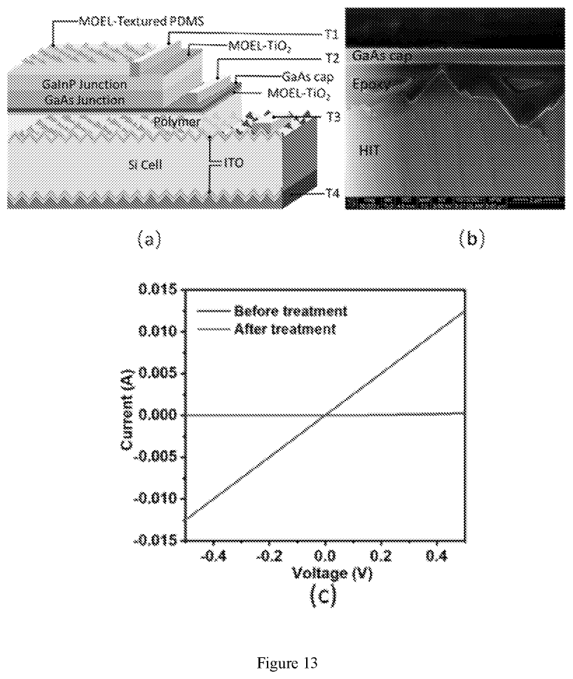

A bonded 2T GaInP/GaAs//Si tandem solar cell comprising a polymer layer is demonstrated. The GaInP/GaAs 2J top cell is bonded on a HIT Si bottom cell by selected polymer. FIG. 13(a) illustrates the final structure of the device. To enhance the photocurrent of subcells, multiple optical enhancement layers were incorporated in the tandem cell. An 80 nm TiO₂ layer was deposited at the rear of the III-V cell by spray pyrolysis before bonding to provide the refractive index grading at the semiconductor/epoxy interface. Another 80 nm TiO₂ layer was sputtered onto the front surface of the III-V subcell after bonding to reduce the refractive index mismatch at the air/III-V interface. The sputtering approach was used because the spray pyrolysis requires high-temperature annealing at 500° C. which would damage the polymer layer. Finally, a PDMS film with texture replicated from the textured front surface of Si cell was attached on the top of sputtered TiO₂ layer to reduce the broadband reflection and extend the effective optical path length.

FIG. 13(b) shows the SEM image of the bonding interface. The space between the III-V top cell and the textured front surface of the Si bottom cell was fully filled by epoxy. After the standard cyclic electrical treatment through metal contacts at the back cap layer of III-V top cell and the front surface of Si bottom cell (T2 and T3), a conductive polymer layer was obtained with a resistance of 40Ω, as shown in FIG. 13(c). The higher resistance here than bonded III-V cells on Si wafer and ITO glass by polymer layer should be attributed to the non-uniformity of epoxy thickness due to the textured Si surface. The resistance could be further reduced by optimizing the electrical treatment procedure for textured surface bonding.

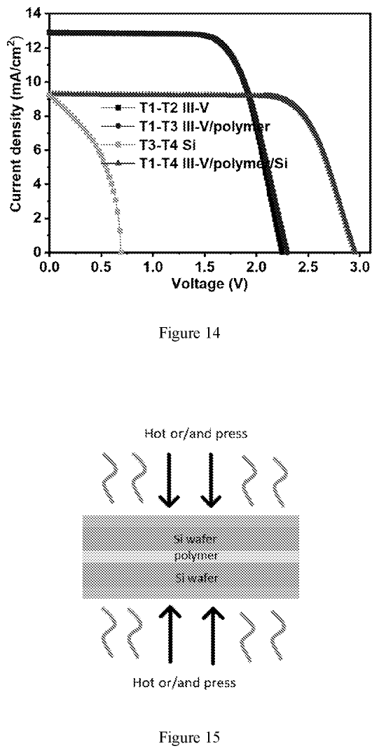

FIG. 14 shows the performance of the GaInP/GaAs//Si tandem cell, together with that of the single III-V and Si subcells. The detailed parameters are summarised in Table 1. The JV curve measured across the polymer layer through metal contacts on the front surface of the III-V cell (T1) and the front surface of Si bottom cell (T3) nearly aligns with that of only III-V cell without passing through polymer layer measured by T1 and T2. The 1.80% drop of FF to 68.81% in the T1-T3 measurement could be attributed to the combined resistance from the polymer layer and the lateral sheet resistance along the front surface of the Si subcell. The lateral resistance of Si should be the main reason for FF drop, since T1-T4 measurement of the whole tandem cell, which only involves vertical transport of carriers within Si cell, yields a high FF of 74.54%. The higher FF of the tandem cell than that of each subcell implies that the performance of the bonded III-V//Si tandem cell by polymer layer is limited by the quality of subcells, rather than the polymer layer bonding layer.

TABLE 1
Device characteristics of III-V top cell, Si bottom cell, and
III-V//Si tandem cell measured through different terminals.

| | V_{OC} | J_{SC} | FF | Efficiency |
|---|---|---|---|---|
| | (V) | (mA/cm²) | (%) | (%) |
| GaInP/GaAs (T1-T2) | 2.246 | 12.89 | 70.61 | 20.44 |
| aInP/GaAs(T1-T2) | | | | |
| GaInP/GaAs/polymer | 2.298 | 12.87 | 68.81 | 20.35 |
| (T1-T3) | | | | |
| Si (T3-T4) | 0.682 | 9.23 | 61.35 | 3.86 |
| GaInP/GaAs/polymer/Si | 2.953 | 9.28 | 74.54 | 20.43 |
| (T1-T4) | | | | |

The overall efficiency of the bonded 2T GaInP/GaAs//Si tandem solar cell is 20.43%, with a V_{OC} of 2.953 V, J_{SC} of 9.28 mA/cm2, and FF of 74.54%. The V_{OC} of the tandem cell was almost the sum of that of III-V (2.246 V) and Si (0.682 V) subcells, indicating the no voltage drop caused by the polymer layer. Such V_{OC} is higher than that of other reported tandem cells, which demonstrated the voltage drops after electrical connection through wire bonding (140 mV)^{[5]}, smart stack (140 mV)^{[6]}, ZnO-based TCA bonding (200 mV)^{[7]}, and metal balls bonding (40 mV).^{[8]} Moreover, the FF of the bonded III-V//Si tandem cell by polymer layer is higher than that obtained using metal ball bonding with the expensive bonding materials in the previous report.^{[8]}

### Example 7—Reduced Resistivity for Selected Materials

For specific materials were treated at different temperatures and/or pressures in order to reduce the resistivity of said materials (as exemplified in FIG. 15). The results are shown in Table 2.

TABLE 2
Resistance of selected materials under different conditions

| Material | Resistivity (Ω · m) | Temperature (° C.) | Pressure (MPa) |
|---|---|---|---|
| EVA | 150 | 150 | 0.5 |
| PMMA | 50 | 200 | 0.5 |
| PVA | 50 | 100 | 0.5 |
| Super glue | 50 | RT | 0.1 |

It will be appreciated by persons skilled in the art that numerous variations and/or modifications may be made to the above-described embodiments, without departing from the broad general scope of the present disclosure. The present embodiments are, therefore, to be considered in all respects as illustrative and not restrictive.

### REFERENCES

[1] K. Makita et al., “III-V//Si multi-junction solar cells with 30% efficiency using smart stack technology with Pd nanoparticle array,” Progress in Photovoltaics: Research and Applications, vol. 28, no. 1, pp. 16-24, 2020, doi: 10.1002/pip.3200.
[2] U. Heitmann et al., “Pathways and Potentials for III-V on Si Tandem Solar Cells Realized Using a ZnO-Based Transparent Conductive Adhesive,” IEEE Journal of Photovoltaics, vol. 11, no. 1, pp. 85-92, 2021, doi: 10.1109/JPHOTOV.2020.3038604.
[3] T. R. Klein et al., “Transparent Conductive Adhesives for Tandem Solar Cells Using Polymer-Particle Composites,” ACS Appl Mater Interfaces, vol. 10, no. 9, pp. 8086-8091, 2018, doi: 10.1021/acsami.8b00175.
[4] C. D. Bailie et al., “Semi-transparent perovskite solar cells for tandems with silicon and CIGS,” Energy and Environmental Science, vol. 8, no. 3, pp. 956-963, 2015, doi: 10.1039/c4ee03322a.
[5] Y. C. Kao et al., “Performance comparison of III-V//Si and III-V//InGaAs multi-junction solar cells fabricated by the combination of mechanical stacking and wire bonding,” Scientific Reports, vol. 9, no. 1, pp. 1-11, 2019, doi: 10.1038/s41598-019-40727-y.
[6] H. Mizuno, K. Makita, T. Tayagaki, T. Mochizuki, T. Sugaya, and H. Takato, “High-efficiency III-V//Si tandem solar cells enabled by the Pd nanoparticle array-mediated ‘smart stack’ approach,” Applied Physics Express, vol. 10, no. 7, 2017, doi: 10.7567/APEX.10.072301.
[7] U. Heitmann et al., “Challenges in the Fabrication of a Glued III-V on Si Tandem Solar Cell Using a ZnO-Based TCA,” Conference Record of the IEEE Photovoltaic Specialists Conference, pp. 1121-1124, 2021, doi: 10.1109/PVSC43889.2021.9518738.
[8] R. H. Horng, Y. C. Kao, A. Sood, P. L. Liu, W. C. Wang, and Y. J. Teseng, “Gainp/gaas/poly-si multi-junction solar cells by in metal balls bonding,” Crystals (Basel), vol. 11, no. 7, pp. 1-9, 2021, doi: 10.3390/cryst11070726.
[9] Sakata T, Kajiya D, Saitow K. Brush Printing Creates Polarized Green Fluorescence: 3D Orientation Mapping and Stochastic Analysis of Conductive Polymer Films [J]. ACS Applied Materials & Interfaces, 2020, 12(41): 46598-46608.
[10] Tang L, Thomsen L, McNeill C R. Chain alignment and charge transport anisotropy in blade-coated P (NDI2OD-T2)/PS blend films[J]. ACS Applied Polymer Materials, 2022, 4(8): 5501-5514.
[11] Radhakrishnan K. Singh S P. Collapse of a Confined Polyelectrolyte Chain under an AC Electric Field [J]. Macromolecules, 2021, 54(17): 7998-8007.
[12] Chen Z, Chan Y T, Miyajima D, et al. A design principle of polymers processable into 2D homeotropic order[J]. Nature Communications, 2016, 7(1): 13640.
[13] Liu W, Lei Z, Yang R, et al. Facile Approach to Enhance Electrical and Thermal Performance of Conducting Polymer PEDOT:PSS Films via Hot Pressing[J]. ACS Applied Materials & Interfaces, 2022, 14(8): 10605-10615.
[14] Botiz I. Prominent processing techniques to manipulate semiconducting polymer microstructures[J]. Journal of Materials Chemistry C, 2023, 11(2): 364-405.

1. A polymer material comprising one or more polymers, optionally one or more insulating polymers or one or more conductive polymers, comprising one or more electron rich domains, wherein when:
a sufficiently strong electric field is applied across the one or more polymers and/or
a sufficiently strong magnetic field is applied across the one or more polymers; and/or
a sufficiently high temperature is applied across the one or more polymers; and/or
a sufficiently strong pressure is applied across the one or more polymers,
the electrical conductivity of the polymer material is increased.

2. A polymer material comprising one or more polymers, optionally one or more insulating polymers or one or more conductive polymers, comprising one or more electron rich domains, wherein when:
the polymer material is disposed between a plurality of layers, each layer independently selected from: one or more metals, one or more semiconductors, one or more materials capable conducting a charge, and mixtures thereof; and
at least one of:
a sufficiently strong electric field is applied across the one or more polymers; and/or
a sufficiently strong magnetic field is applied across the one or more polymers; and/or
a sufficiently high temperature is applied across the one or more polymers; and/or
a sufficiently strong pressure is applied across the one or more polymers,
the electrical conductivity of the polymer material is increased.

3. An electrically conductive polymer material formed from the polymer material of claim 1 or claim 2, wherein the one or more polymers, optionally one or more insulating polymers, are exposed to at least one of: the sufficiently strong electric field, the sufficiently strong magnetic field, the sufficiently high temperature and/or the sufficiently strong pressure.

4. The electrically conductive polymer material of claim 3, wherein the conductive polymer material is a conductive adhesive.

5. The electrically conductive polymer material of claim 3, wherein the conductive polymer material is a transparent conductive adhesive.

6. A method of producing an electrically conductive polymer material, the method comprising applying at least one of:
a sufficiently strong electric field; and/or
a sufficiently strong magnetic field; and or
a sufficiently high temperature; and/or
a sufficiently strong pressure,
across one or more polymers (optionally one or more insulating polymers), comprising one or more electron rich domains, wherein the electrical conductivity of the one or more polymers is increased.

7. A method of improving the electrical conductivity of a polymer material comprising one or more polymers, the method comprising applying at least one of:
a sufficiently strong electric field; and/or
a sufficiently strong magnetic field; and/or
a sufficiently high temperature; and/or
a sufficiently strong pressure,
across the one or more polymers comprising one or more electron rich domains, wherein the electrical conductivity of the conductive polymer material is increased.

8. A method of producing an electrically conductive polymer material, the method comprising:
disposing one or more polymers, optionally one or more insulating polymers, comprising one or more electron rich domains between a plurality of layers, each layer independently selected from: one or more metals, one or more semiconductors, one or more materials capable conducting a charge, and mixtures thereof; and
applying at least one of:
a sufficiently strong electric field; and/or
a sufficiently strong magnetic field; and/or
a sufficiently high temperature and/or
a sufficiently strong pressure,
across the one or more polymers, wherein the electrical conductivity of the one or more polymers is increased.

9. Use of one or more polymers (optionally one or more insulating polymers), comprising one or more electron rich domains, in a polymer material, to produce an electrically conductive polymer, wherein when at least one of:
a sufficiently strong electric field; and/or
a sufficiently strong magnetic field; and/or
a sufficiently high temperature; and/or
a sufficiently strong pressure,
is applied across the one or more polymers, the electrical conductivity of the polymer material is increased.

10. The method or use of any one of claims 6 to 9, wherein the electrically conductive polymer material is a conductive adhesive, or a transparent conductive adhesive.

11. Use of one or more polymers, optionally one or more insulating polymers, for physically and electronically connecting a plurality of layers, each layer independently selected from: one or more metals, one or more semiconductors, one or more materials capable conducting a charge, and mixtures thereof, wherein when:
the one or more polymers are disposed between the plurality of layers and
at least one of:
a sufficiently strong electric field; and/or
a sufficiently strong magnetic field; and/or
a sufficiently high temperature; and/or
a sufficiently strong pressure,
is applied across the one or more polymers,
the electrical conductivity of the one or more polymers is increased.

12. The polymer material, electrically conductive polymer material, method, or use, of any one of the preceding claims, wherein the electric field has a strength of at least 10, 20, 30, 40, 50, 60, 70, 80, 90, or 100 V/m.

13. The polymer material, electrically conductive polymer material, method, or use, of any one of the preceding claims, wherein the one or more polymers comprise the one or more electron rich domains present in a polymer backbone and/or sidechain.

14. The polymer material, electrically conductive polymer material, method, or use, of any one of the preceding claims, wherein the one or more polymers comprise one or more electron rich domains selected from one or more optionally substituted: double bonds, cyclic groups, heterocyclic rings, aryl rings, heteroaryl rings, fluorine or fluorine containing groups, cyano groups, carbonyls, aldehydes, hydroxyls, esters, carboxylic acids, glycidyl groups, amines, imines, or atoms with unbonded electrons, optionally selected from Li, Cu, Fe, Si, S, O, F, Br, and mixtures thereof.

15. The polymer material, electrically conductive polymer material, method, or use, of any one of the preceding claims, wherein the one or more polymers comprise one or more polymers selected from: poly(ethylene-vinyl acetate), poly(methyl methacrylate), polylactic acid, poly(acrylonitrile butadiene styrene), Nafion, a nylon, Nylon 6, Nylon 6-6, a polyamide, polybutylene terephthalate, a polycarbonate, a polyetheretherketone, a polyetherketoneketone, a polyetherketone, a polyketone, polyethylene terephthalate (pet), a polyimide, a polyoxymethylene plastic, a polyphenylene sulfide, a polyphenylene oxide, a polysulphone, a polyester resin, an epoxy resin, and mixtures thereof.

16. The polymer material, electrically conductive polymer material, method, or use, of any one of the preceding claims, wherein the one or more polymers comprises or consists essentially of one or more homopolymers, copolymers, or a mixture thereof.

17. The polymer material, electrically conductive polymer material, method, or use, of any one of the preceding claims, wherein the one or more polymers comprise or consist essentially of one or more homopolymers.

18. The polymer material, electrically conductive polymer material, method, or use, of any one of the preceding claims, wherein the one or more polymers comprise or consist essentially of one or more copolymers.

19. The polymer material, electrically conductive polymer material, method, or use, of any one of the preceding claims, wherein the one or more polymers comprise or consist essentially of one or more copolymers, wherein one or more of the copolymers are derived from or at least 2, 3 or 4 monomer groups.

20. The polymer material, electrically conductive polymer material, method, or use, of any one of the preceding claims, wherein the one or more polymers comprise polymers derived from monomers selected from: methyl acrylate, ethyl acrylate, n-propyl acrylate, isopropyl acrylate, n-butyl acrylate, isobutyl acrylate, sec-butyl acrylate, tert-butyl acrylate, amyl acrylate, hexyl acrylate, 2-ethylhexyl acrylate, octyl acrylate, tert-octyl acrylate, 2-chloroethyl acrylate, 2-bromoethyl acrylate, 4-chlorobutyl acrylate, cyanoethyl acrylate, 2-acetoxyethyl acrylate, dimethylaminoethyl acrylate, benzyl acrylate, methoxybenzyl acrylate, 2-chlorocyclohexyl acrylate, cyclohexyl acrylate, furfuryl acrylate, tetrahydrofurfuryl acrylate, phenyl acrylate, 5-hydroxypentyl acrylate, 2-methoxyethyl acrylate, 3-methoxybutyl acrylate, 2-ethoxybutyl acrylate, 2-ethoxyethyl acrylate, 2-isopropoxy acrylate, 2-butoxyethyl acrylate, 2-(2-methoxyethoxy)ethyl acrylate, 2-(2-methoxyethoxy)ethyl acrylate, 2-(2-butoxyethoxy)ethyl acrylate, ω-methoxypolyethylene glycol acrylate, 1-bromo-2-methoxyethyl acrylate, and 1,1-dichloro-2-ethoxyethyl acrylate; methacrylic esters, optionally: methyl methacrylate, ethyl methacrylate, n-propyl methacrylate, isopropyl methacrylate, n-butyl methacrylate, isobutyl methacrylate, sec-butylmethacrylate, tert-butylmethacrylate, amylmethacrylate, hexylmethacrylate, cyclohexylmethacrylate, benzyl methacrylate, chlorobenzyl methacrylate, octyl methacrylate, stearylmethacrylate, sulfopropylmethacrylate, N-ethyl-N-phenylaminoethyl methacrylate, 2-(3-phenylpropyloxy)ethyl methacrylate, dimethylaminophenoxyethyl methacrylate, furfuryl methacrylate, tetrahydrofurfuryl methacrylate, phenyl methacrylate, cresyl methacrylate, naphthyl methacrylate, 2-hydroxyethyl methacrylate, 4-hydroxybutyl methacrylate, triethylene glycol monomethacrylate, dipropylene glycol monomethacrylate, 2-methoxyethyl methacrylate, 3-methoxybutyl methacrylate, 2-acetoxyethyl methacrylate, 2-acetoacetoxyethyl methacrylate, 2-ethoxyethyl methacrylate, 2-isopropoxyethyl methacrylate, 2-butoxyethyl methacrylate, 2-(2-methoxyethoxy)ethyl methacrylate, 2-(2-ethoxyethoxy)ethyl methacrylate, 2-(2-butoxyethoxy)ethyl methacrylate, ω-methoxypolyethylene glycol methacrylate, acryl methacrylate, and methacrylic acid dimethylaminoethylmethyl chloride salt; vinylesters, optionally: vinylacetate, vinyl propionate, vinyl butyrate, vinyl isobutyrate, vinyl caproate, vinyl chloroacetate, vinylmethoxy acetate, vinylphenyl acetate, vinyl benzoate and vinyl salicylate; acrylamides, optionally: acrylamide, ethylacrylamide, propylacrylamide, isopropylacrylamide, n-butylacrylamide, sec-butylacrylamide, tert-butylacrylamide, cyclohexylacrylamide, benzylacrylamide, hydroxymethylacrylamide, methoxyethylacrylamide, dimethylaminoethylacrylamide, phenylacrylamide, dimethylacrylamide, diethylacrylamide, β-cyanoethylacrylamide, N-(2-acetoacetoxyethyl)acrylamide, and diacetoneacrylamide; methacrylamides, optionally: methacrylamide, methylmethacrylamide, ethylmethacrylamide, propylmethacrylamide, isopropylmethacrylamide, n-butylmethacrylamide, sec-butylmethacrylamide, tert-butylmethacrylamide, cyclohexylmethacrylamide, benzylmethacrylamide, hydroxymethacrylamide, chlorobenzylmethacrylamide, octylmethacrylamide, stearylmethacrylamide, sulfopropylmethacrylamide, N-ethyl-N-phenylaminoethylmethacrylamide, 2-(3-phenylpropyloxy)ethylmethacrylamide, dimethylaminophenoxyethylmethacrylamide, furfurylmethacrylamide, tetrahydrofurfurylmethacrylamide, phenylmethacrylamide, cresylmethacrylamide, naphthylmethacrylamide, 2-hydroxyethylmethacrylamide, 4-hydroxybutylmethacrylamide, triethylene glycol monomethacrylamide, dipropylene glycol monomethacrylamide, 2-methoxyethylmethacrylamide, 3-methoxybutylmethacrylamide, 2-acetoxyethylmethacrylamide, 2-acetoacetoxyethylmethacrylamide, 2-ethoxyethylmethacrylamide, 2-isopropoxyethylmethacrylamide, 2-butoxyethylmethacrylamide, 2-(2-methoxyethoxy)ethylmethacrylamide, 2-(2-ethoxyethoxy)ethylmethacrylamide, 2-(2-butoxyethoxy)ethylmethacrylamide, @-methoxypolyethylene glycol methacrylamide, acrylmethacrylamide, dimethylaminomethacrylamide, diethylaminomethacrylamide, cyanoethylmethacrylamide, and N-(2-acetoacetoxyethyl)methacrylamide; olefins, optionally: dicyclopentadiene, ethylene, propylene, 1-butene, 1-pentene, vinyl chloride, vinylidene chloride, isoprene, chloroprene, butadiene, and 2,3-dimethylbutadiene; styrenes, optionally: styrene, methylstyrene, dimethylstyrene, trimethylstyrene, ethylstyrene, isopropylstyrene, chloromethylstyrene, methoxystyrene, acetoxystyrene, chlorostyrene, dichlorostyrene, bromostyrene, and vinylbenzoic acid methyl ester; vinyl ethers, optionally: methylvinyl ether, butylvinyl ether, hexylvinyl ether, methoxyethylvinyl ether and dimethylaminoethylvinyl ether; butyl crotonate; hexyl crotonate; dibutyl itaconate; dimethyl maleate; dibutyl maleate; dimethyl fumarate; dibutyl fumarate; methyl vinyl ketone; phenyl vinyl ketone; methoxyethyl vinyl ketone; glycidyl acrylate; glycidyl methacrylate; N-vinyloxazolidone; N-vinylpyrrolidone; acrylonitrile; methacrylonitrile; methylene moronnitrile; vinylidene; and mixtures thereof.

21. The polymer material, electrically conductive polymer material, method, or use, of any one of the preceding claims, wherein the one or more polymers comprise polymers derived from monomers selected from: ethylene, butylene, vinyl acetate, methyl methacrylate, lactic acid, butadiene, acrylonitrile, styrene, tetrafluoroethylene, terephthalate, cyclic groups, heterocyclic groups, aryl groups, heteroaryl groups, optionally comprising one or more N, O and/or S atoms, and mixtures thereof.

22. The polymer material, electrically conductive polymer material, method, or use, of any one of the preceding claims, wherein the one or more polymers comprise one or more intrinsic conductive polymer material, optionally selected from: poly(3,4-ethylenedioxythiophene)polystyrene sulfonate (PEDOT:PSS), poly(3-hexylthiophene) (P3HT), polyacetylene (PA), polyaniline (PANI), polypyrrole (PPy), polythiophene (PTH), poly(para-phenylene) (PPP), poly(phenylenevinylene) (PPV), and polyfuran (PF), and mixtures thereof.

23. The polymer material, electrically conductive polymer material, method, or use, of any one of the preceding claims, wherein the one or more polymers comprise one or more extrinsic conductive polymer material, optionally comprising or consisting of a matrix of polymer with a percentage of conducting material, wherein the conducting material is optionally selected from: metal particles, metal coated particles, indium tin oxide particles, powdered graphite, and mixtures thereof.

24. The polymer material, electrically conductive polymer material, method, or use, of any one of the preceding claims, wherein the one or more polymers are independently fabricated by one or more processes selected from: hot pressing, drop casting and optional press, spin coating, spray coating, blade coating, sputtering, thermal evaporation, chemical vapour deposition, atomic layer deposition, electrochemical deposition, electron beam deposition, Langmuir-Blodgett deposition, and colloidal deposition, and mixtures thereof.

25. The polymer material, electrically conductive polymer material, method, or use, of any one of the preceding claims, wherein the increase in the electrical conductivity is reversible or partially reversible.

26. The polymer material, electrically conductive polymer material, method, or use, of claim any one of the preceding claims, wherein the electrical conductivity is reversible or partially via heat treatment, optionally thermal annealing or cooling, optionally ultra-cooling.

27. A polymer material, or an electrically conductive polymer material obtained from the method according to any one of the preceding claims, wherein the polymer material is optionally a conductive polymer adhesive, optionally a transparent conductive adhesive.

28. A device comprising a polymer material, or an electrically conductive polymer material according to any one of the preceding claims.

29. A device comprising: a first layer; a second layer; and a third layer comprising transparent conductive adhesive, wherein:
the third layer is arranged between the first and second layers and
the third layer comprising the polymer material, or the electrically conductive polymer material according to any one of claims 1 to 27.

30. The device according to claim 28 or claim 29, wherein the polymer material, or the electrically conductive polymer material is a conductive adhesive, optionally a transparent conductive adhesive.

31. The device according to claim 28 or claim 29, wherein the third layer is configured to provide no electrical conductivity along a direction parallel to the plane of the third layer.

32. The device according to any one of claims 28 to 31, wherein at least one of the first layer or the second layer comprises a semiconductor.

33. The device according to any one of claims 28 to 32, wherein at least one of the first layer or the second layer comprises a metal.

34. The device according to any one of claims 28 to 33, wherein at least one of the first layer or the second layer comprises a transparent conducting material.

35. The device according to any one of claims 28 to 32, wherein the first layer is a semiconductor substrate and the second layer is a silicon substrate

36. The device according to claim 35, wherein a surface of the silicon substrate in contact with the third layer is textured.

37. The device according to claim 29, further comprising: a top photovoltaic cell; and a bottom photovoltaic cell, wherein:
the first layer is arranged between the top photovoltaic cell and the third layer, and
the second layer is arranged between the bottom photovoltaic cell and the third layer.

38. The device according to claim 29, wherein: the first layer is a photovoltaic cell, and the second layer is a back sheet comprising a first area of patterned conductors.

39. The device according to claim 38, wherein the back sheet further comprises a second area that is transparent to solar radiation.

40. A photovoltaic power generating device comprising the polymer material, or the electrically conductive polymer material according to any one of claims 1 to 27 as a conductive layer and/or intermediate layer.

41. The photovoltaic power generating device of claim 41 comprising, consisting essentially of or consisting of tandem solar cells comprising the polymer material, or the electrically conductive polymer material according to any one of claims 1 to 27.

42. The photovoltaic power generating device of claim 41 or claim 42, wherein the polymer material, or the electrically conductive polymer material, is present as at least one intermediate layer.

43. Use of the polymer material, or the electrically conductive polymer material according to any one of claims 1 to 27 in: a battery, an organic thin-film transistor, an organic light-emitting diodes (OLEDs), a bioelectronics device, a surgical device and/or cell biology.
